(19) United States
(12) Patent Application Publication
(10) Pub. No.: US 2005/0195673 A1
(43) Pub. Date: Sep. 8, 2005

(54) Magnetic random access memory having memory cells configured by use of tunneling magnetoresistive elements

(76) Inventors: Yoshiaki Asao, Sagamihara-shi (JP); Yoshihisa Iwata, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/617,666

(22) Filed: Jul. 14, 2003

(30) Foreign Application Priority Data
Jul. 15, 2002 (JP) 2002-206171

(51) Int. Cl. G11C 7/00

(52) U.S. Cl. 365/222

(57) ABSTRACT

A magnetic random access memory includes memory cells each including a TMR element and a selection element, and a read circuit which reads storage information from the TMR element by applying read voltage to a selected one of the memory cells and causing a current to flow through the TMR element via the selection element. The read circuit includes a voltage setting section used to apply voltage which makes a resistance variation rate of the TMR element substantially equal to half a resistance variation rate thereof obtained when 0 V is applied across the TMR element to the TMR element at the information read time.

### CROSS-REFERENCE TO RELATED APPLICATIONS

This application is based upon and claims the benefit of priority from the prior Japanese Patent Application No. 2002-206171, filed Jul. 15, 2002, the entire contents of which are incorporated herein by reference.

### BACKGROUND OF THE INVENTION

1. Field of the Invention

This invention relates to a magnetic random access memory (MRAM) having memory cells configured by use of tunneling magnetoresistive elements, which store information by use of the tunneling magnetoresistive effect.

2. Description of the Related Art

Recently, a large number of different kinds of memory which store information based on new principles has been proposed. As one such memory, there is provided a memory which utilizes the tunneling magnetoresistive (hereinafter referred to as TMR) effect proposed by Roy Scheuerlein et al., that is, a so-called magnetic random access memory (for example, refer to ISSCC2000 Technical Digest p. 128 “A 10ns Read and Write Non-Volatile Memory Array Using a Magnetic Tunnel Junction and FET Switch in each Cell”).

The magnetic random access memory stores information of “1”, “0” by use of the TMR elements. As shown in FIG. 1, a TMR element has a structure in which an insulating layer (tunnel barrier) 13 is disposed between two magnetic layers (ferromagnetic layers) 11, 12. Information stored in the TMR element 10 is based on whether the spin directions of the two magnetic layers 11, 12 are parallel or anti-parallel.

In this case, the parallel spin directions indicate that the spin directions of the two magnetic layers 11, 12 are set in the same direction as shown in FIG. 2A and the anti-parallel spin directions indicate that the spin directions of the two magnetic layers 11, 12 are set in parallel and opposite to each other as shown in FIG. 2B (the spin directions are indicated by arrows).

Generally, an anti-ferromagnetic layer 14 is arranged on one of the two magnetic layers 11, 12. The anti-ferromagnetic layer 14 is a member to easily rewrite information by fixing the spin direction of the magnetic layer 12 which is one of the two magnetic layers and changing only the spin direction of the other magnetic layer 11. The anti-ferromagnetic layer 14 is called a fixing layer. The magnetic layer 12 on one side is called a pinned layer and the magnetic layer 11 on the other side is called a memory layer or recording layer.

When the spin directions of the two magnetic layers (memory layer and pinned layer) 11, 12 are set parallel as shown in FIG. 2A, a tunnel current flowing through the insulating layer 13 disposed between the two magnetic layers 11, 12 becomes larger and the resistance (tunnel resistance) of the TMR element 10 becomes minimum. This state is defined as “1”. Further, when the spin directions of the two magnetic layers 11, 12 are set anti-parallel as shown in FIG. 2B, a tunnel current flowing through the insulating layer 13 disposed between the two magnetic layers 11, 12 becomes smaller and the tunnel resistance becomes maximum. This state is defined as “0”.

Next, the principle of the write operation with respect to the magnetic random access memory using the TMR element 10 as a memory cell is simply explained with reference to FIG. 3.

TMR elements MC11 to MCnm functioning as memory cells are arranged in a matrix form. The TMR elements MC11 to MCnm are arranged near the intersecting positions between write word lines WL1 to WLn and bit lines (data selection lines) BLI to BLm. The write operation is performed by causing currents to flow through a selected write word line WLi (i=1 to n) and bit line BLj (j=1 to m) and setting the spin directions of the memory layer in the TMR element MCij parallel or anti-parallel to the pinned layer by use of a magnetic field created by the currents flowing through the lines WLi and BLj.

For example, as shown in FIG. 3, at the write time, a current is caused to flow through the bit line BL3 only in one direction and a current is caused to flow through the write word line WL2 in one direction or in the other direction according to write information (data). When a current is caused to flow through the write word line WL2 in one direction, the spin direction of the memory layer of the TMR element MC23 becomes parallel to the pinned layer (“1” state is set). On the other hand, when a current is caused to flow through the write word line WL2 in the other direction, the spin direction of the memory layer of the TMR element MC23 becomes anti-parallel to the pinned layer (“0” state is set).

The principle that the spin direction of the pinned layer of each of the TMR elements MC11 to MCnm is changed is as follows.

As shown by TMR curves of FIG. 4, if a magnetic field Hx is applied in an easy-axis (long side) direction of the TMR element, the resistance of the TMR element is changed by approximately 17%. The resistance variation rate, that is, the ratio of the resistances before and after the change is called the MR ratio. The MR ratio is changed according to the property of the magnetic layer. At present, a TMR element in which the MR ratio is approximately 50% is obtained by adequately selecting a material of the magnetic layer.

The resultant magnetic field of the magnetic field Hx in the easy-axis direction and a magnetic field Hy in the hard-axis direction (short side) direction is applied to the TMR element. As shown by solid lines and broken lines in FIG. 4, the magnitude of the magnetic field Hx in the easy-axis direction which is required to change the resistance of the TMR element is changed according to the magnitude of the magnetic field Hy in the hard-axis direction. By using the phenomenon, data can be written into a TMR element which is one of the memory cells arranged in a matrix form and lies at the intersection between the selected write word line and the selected bit line.

The asteroid curve of the TMR element indicated by solid lines in FIG. 5 can be obtained, for example. That is, if the magnitude of the resultant magnetic field of the magnetic field Hx in the easy-axis direction and the magnetic field Hy in the hard-axis direction lies outside (for example, as indicated by the positions of black dots) the asteroid curve (solid lines), the spin direction of the magnetic layer can be inverted.

On the other hand, if the magnitude of the resultant magnetic field of the magnetic field Hx in the easy-axis direction and the magnetic field Hy in the hard-axis direction lies inside (for example, as indicated by the positions of white dots) the asteroid curve (solid lines), the spin direction of the magnetic layer cannot be inverted.

Therefore, the operation of writing data into the TMR element can be controlled by changing the magnitude of the resultant magnetic field of the magnetic field Hx in the easy-axis direction and the magnetic field Hy in the hard-axis direction and changing the position of the magnitude of the resultant magnetic field in the Hx-Hy plane.

The read operation can be easily performed by causing a current to flow through a selected TMR element and detecting the resistance of the selected TMR element.

For example, switch elements are connected in series with the TMR elements and only one of the switch elements which is connected to the selected read word line is turned ON to create a current passage. As a result, a current flows only in the selected TMR element and data of the TMR element can be read.

The read operation is performed by detecting a current I which flows in a state in which preset voltage V0 is applied across the series circuit of the TMR element and switch element by use of a sense amplifier. As described before, the “1” storage state is set up when the spin directions of the fixing layer and recording layer are the same and it is assumed that a current Ip flows at this time. Further, the “0” storage state is set up when the spin directions of the fixing layer and recording layer are different and it is assumed that a current Ia flows at this time. Since the resistance of the TMR element is lower in the “1” state than in the “0” state, Ip>Ia. Generally, the read margin ΔI becomes sufficiently larger as the ΔI=Ip-Ia becomes larger. Therefore, it is considered to make the read margin ΔI larger as the voltage V0 is increased. However, it is known that the MR ratio of the TMR element becomes lower as voltage E applied across the TMR element becomes higher. Therefore, it is not easy to increase the read margin ΔI.

As described above, the conventional magnetic random access memory has a problem that the MR ratio of the TMR element becomes lower and the read margin cannot be increased if the voltage applied across the series circuit of the TMR element and switch element is increased in order to make the read margin larger.

### BRIEF SUMMARY OF THE INVENTION

A magnetic random access memory according to an aspect of the present invention comprises memory cells each including a tunneling magnetoresistive element which stores information by use of the tunneling magnetoresistive effect and a selection element which selects the tunneling magnetoresistive element, and a read circuit which reads information from the tunneling magnetoresistive element by applying read voltage to the memory cell and causing a current to flow through the tunneling magnetoresistive element via the selection element, wherein the read circuit includes a voltage setting section used to apply voltage which makes a resistance variation rate of the tunneling magnetoresistive element substantially equal to half a resistance variation rate obtained when 0 V is applied across the tunneling magnetoresistive element to the tunneling magnetoresistive element at the information read time.

A magnetic random access memory according to another aspect of the present invention comprises memory cells each including a tunneling magneto-resistive element which stores information by use of the tunneling magnetoresistive effect and a selection element which selects the tunneling magnetoresistive element, and a read circuit which reads information from the tunneling magnetoresistive element by applying read voltage to the memory cell and causing a current to flow through the tunneling magnetoresistive element via the selection element, wherein the read circuit includes a voltage setting section used to apply voltage which is higher than the voltage applied to the tunneling magnetoresistive element by at least a voltage drop occurring in the selection element to the tunneling magnetoresistive element at the information read time.

Further, a magnetic random access memory according to still another aspect of the present invention comprises tunneling magnetoresistive elements each of which stores information by use of the tunneling magnetoresistive effect, bit lines connected to one-side ends of the tunneling magnetoresistive elements, word lines connected to the other ends of the tunneling magnetoresistive elements, and a read circuit which reads information from the tunneling magnetoresistive element by applying read voltage to the memory cell and causing a current to flow through the tunneling magnetoresistive element, wherein the read circuit includes a voltage setting section used to apply voltage which makes a resistance variation rate of the tunneling magnetoresistive element substantially equal to half a resistance variation rate obtained when 0 V is applied across the tunneling magnetoresistive element to the tunneling magnetoresistive element at the information read time.

### BRIEF DESCRIPTION OF THE SEVERAL VIEWS OF THE DRAWING

FIG. 1 is a cross-sectional view showing an example of the configuration of a TMR element used in a magnetic random access memory,

FIGS. 2A and 2B are cross-sectional views for illustrating spin directions of pinned layers of the TMR elements,

FIG. 3 is a schematic view for illustrating the principle of the write operation with respect to the TMR element,

FIG. 4 is a characteristic diagram showing a TMR curve,

FIG. 5 is a characteristic diagram showing an asteroid curve,

FIG. 6 is a circuit diagram showing an example of the configuration of a magnetic random access memory according to a first embodiment of this invention and showing a memory cell array section and sense amplifier section extracted with much attention paid to the circuit section which is associated with the read operation of the magnetic random access memory,

FIG. 7 is a cross-sectional view showing an example of the structure of each memory cell of the memory cell array shown in FIG. 6,

FIG. 8 is a circuit diagram showing an equivalent circuit at the read time of the magnetic random access memory shown in FIGS. 6 and 7,

FIG. 9 is a cross-sectional view showing an example of the structure of each memory cell of a memory cell array, for illustrating a magnetic random access memory according to a second embodiment of this invention,

FIG. 10 is a circuit diagram showing an equivalent circuit at the read time of the magnetic random access memory shown in FIG. 9,

FIG. 11 is a cross-sectional view showing an example of the structure of each memory cell of a memory cell array, for illustrating a magnetic random access memory according to a third embodiment of this invention,

FIG. 12 is a circuit diagram showing an equivalent circuit at the read time of the magnetic random access memory shown in FIG. 11,

FIG. 13A is a cross-sectional view showing an example of the structure of each memory cell of a memory cell array, for illustrating a magnetic random access memory according to a fourth embodiment of this invention,

FIG. 13B is a circuit diagram showing an equivalent circuit at the read time of the magnetic random access memory shown in FIG. 13A,

FIG. 14A is a cross-sectional view showing an example of the structure of each memory cell of a memory cell array, for illustrating a magnetic random access memory according to a fifth embodiment of this invention,

FIG. 14B is a circuit diagram showing an equivalent circuit at the read time of the magnetic random access memory shown in FIG. 14A,

FIG. 15 is a cross-sectional view showing an example of the structure of each memory cell of a memory cell array, for illustrating a magnetic random access memory according to a sixth embodiment of this invention,

FIG. 16 is a cross-sectional view showing an example of the structure of each memory cell of a memory cell array, for illustrating a magnetic random access memory according to a seventh embodiment of this invention,

FIG. 17 is a cross-sectional view showing an example of the structure of each memory cell of a memory cell array, for illustrating a magnetic random access memory according to an eighth embodiment of this invention,

FIG. 18 is a cross-sectional view showing an example of the structure of each memory cell of a memory cell array, for illustrating a magnetic random access memory according to a ninth embodiment of this invention,

FIG. 19 is a cross-sectional view showing an example of the structure of each memory cell of a memory cell array, for illustrating a magnetic random access memory according to a tenth embodiment of this invention,

FIG. 20 is a cross-sectional view showing an example of the structure of each memory cell of a memory cell array, for illustrating a magnetic random access memory according to an eleventh embodiment of this invention,

FIG. 21 is a block diagram showing a DSL data path portion of a modem for a digital subscriber line (DSL), for illustrating an application example 1 of the MRAM according to any one of the first to eleventh embodiments of this invention,

FIG. 22 is a block diagram showing a portable telephone terminal, for illustrating an application example 2 of the MRAM according to any one of the first to eleventh embodiments of this invention,

FIG. 23 is a top plan view showing an example in which the MRAM is applied to a card (MRAM card) which receives media contents such as smart media, for illustrating an application example 3 of the MRAM according to any one of the first to eleventh embodiments of this invention,

FIG. 24 is a plan view showing a transfer device used to transfer data to an MRAM card,

FIG. 25 is a cross-sectional view showing a transfer device used to transfer data to an MRAM card,

FIG. 26 is a cross-sectional view showing a fitting type transfer device used to transfer data to an MRAM card, and

FIG. 27 is a cross-sectional view showing a slide type transfer device used to transfer data to an MRAM card.

### DETAILED DESCRIPTION OF THE INVENTION

[First Embodiment]

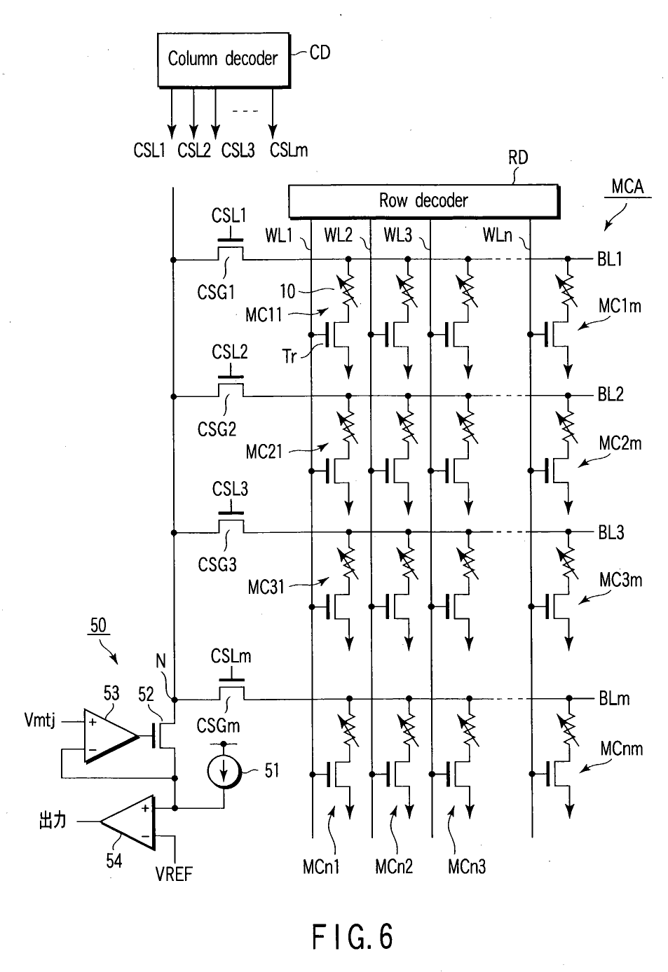

FIGS. 6 and 7 show an example of the schematic configuration of a magnetic random access memory according to a first embodiment of this invention. FIG. 6 is a circuit diagram showing an extracted memory cell array section and a sense amplifier section functioning as a read circuit with much attention paid to a circuit section which is associated with the read operation of the magnetic random access memory. FIG. 7 is a cross-sectional view showing an example of the structure of each memory cell of the memory cell array shown in FIG. 6.

As shown in FIG. 6, a memory cell array MCA has memory cells MC11 to MCnm arranged in a matrix form. Each of the memory cells MC11 to MCnm includes a TMR element 10 and a MOSFET Tr functioning as a selection element (switching element) to select the TMR element 10. Those of the gates of the MOSFETs Tr of the memory cells MC11 to MCnm which are arranged on the same row are connected to a corresponding one of read word lines WL1 to WLn. The sources of the MOSFETs Tr are connected to a source line (not shown). Write word lines (not shown) which extend in the same direction as the read word lines WL1 to WLn are arranged above the read word lines WL1 to WLn. The word lines are supplied with output signals of a row decoder RD. The drain electrodes of the MOSFETs Tr of the memory cells MC11 to MCnm are respectively connected to one-side ends of the TMR elements 10 and the other ends of those of the TMR elements 10 which are arranged on the same column are connected to a corresponding one of bit lines (data selection lines) BL1 to BLm.

One-side ends of the bit lines BL1 to BLm are respectively connected to one-side ends of the current paths of column selection gates CSG1 to CSGm. Output signals (column selection signals) of a column decoder CD are supplied to the gate electrodes of the column selection gates CSG1 to CSGm. The other ends of the current paths of the column selection gates CSG1 to CSGm are commonly connected to a node N of a sense amplifier section 50.

The sense amplifier section 50 functions as a read circuit which reads data from the tunneling magneto-resistive element 10 when read voltage is applied to a selected memory cell and a current is caused to flow through the tunneling magnetoresistive element 10 via the MOSFET Tr. The sense amplifier section 50 includes a current source 51, MOSFET 52, operational amplifiers 53, 54 and the like. One end of the current path of the MOSFET 52 is commonly connected to the other ends of the current paths of the column selection gates CSG1 to CSGm. The gate electrode of the MOSFET 52 is connected to an output terminal of the operational amplifier 53 and the other end of the current path thereof is connected to an inverted input terminal (−) of the operational amplifier 53. Constant potential Vmtj is applied to a non-inverted input terminal (+) of the operational amplifier 53.

Further, the other end of the current path of the MOSFET 52 is connected to a non-inverted input terminal (+) of the operational amplifier 54 and reference potential VREF is applied to an inverted input terminal (−) of the operational amplifier 54.

A constant current is supplied from the current source 51 to the other end of the current path of the MOSFET 52.

The current source 51 functions as a current specifying section which specifies a read current flowing through the TMR element 10 and MOSFET Tr and causes a current of 100 μA to 300 μA to flow, for example.

The operational amplifier 53 functions as a voltage setting section which applies voltage Vh to the tunneling magnetoresistive element 10 at the data read time. The voltage Vh is voltage which causes the resistance variation rate of the tunneling magneto-resistive element 10 to be reduced to substantially half the resistance variation rate attained when 0 V is applied across the tunneling magnetoresistive element 10. Voltage applied across a series circuit of the TMR element 10 and MOSFET Tr at the read time is set according to potential Vmtj applied to the non-inverting input terminal (+) of the operational amplifier 53. In this case, if a lowering in IR due to the wiring resistance and ON resistance of the column selection gate CSG is neglected, read voltage applied across the series circuit of the MOSFET Tr and TMR element 10 corresponds to the constant potential Vmtj.

More preferably, the potential of the node N of the sense amplifier section 50 is set to potential which is higher than read voltage by a voltage drop due to the ON resistance of the MOSFET Tr. Alternatively, the voltage Vh can be set to an optimum value by setting the potential which is higher than the read voltage by a lowering in IR due to the wiring resistance and ON resistance of the column selection gate CSG in addition to the ON resistance of the MOSFET Tr.

Further, the operational amplifier 54 functions as a comparator section to determine “1” or “0” of storage data by comparing read potential with reference potential VREF corresponding to an intermediate value between “1” and “0” of the storage data on the bit lines BL1 to BLm and output the storage data.

The memory cells MC11 to MCnm are configured as shown in FIG. 7, for example. That is, STI (Shallow Trench Isolation) regions 22, 23 are formed on the main surface of a P-type silicon substrate (P-sub) 21 to isolate element regions. N⁺-type impurity diffusion regions 24, 25 used as source, drain regions of a MOSFET Tr are formed on the main surface of the silicon substrate 21 isolated by the STI regions 22, 23. A gate insulating film 26 is formed on that part of the substrate 21 which lies between the source and drain regions 24 and 25 and a gate electrode 27 acting as a read word line WL is formed on the gate insulating film 26. A first inter-level insulating film 28 is formed on the silicon substrate 21 and gate electrode 27. Contact holes 29, 30 are formed in portions of the inter-level insulating film 28 which lie on the source, drain regions 24, 25.

A source line 31 and wiring 32 which are formed of a first-layered metal layer are formed on the inter-level insulating film 28. The source line 31 is electrically connected to the source region 24 via a metal plug 33 formed in the contact hole 29 and the wiring 32 is electrically connected to the drain region 25 via a metal plug 34 formed in the contact hole 30.

A second inter-level insulating film 35 is formed on the inter-level insulating film 28, source line 31 and wiring 32. A contact hole 36 is formed in a portion of the inter-level insulating film 35 which lies on the wiring 32. A write word line 37 and wiring 38 which are formed of a second-layered metal layer are formed on the inter-level insulating film 35. The write word line 37 is formed along the same direction as the read word line (gate electrode 27). Further, the wiring 38 is formed above the wiring 32 and is electrically connected to the wiring 32 via a metal plug 39 buried in the contact hole 36.

A third inter-level insulating film 40 is formed on the second inter-level insulating film 35, write word line 37 and wiring 38. A contact hole 41 is formed in a portion of the inter-level insulating film 40 which lies on the wiring 38. A wiring 42 which is formed of a third-layered metal layer is formed on the inter-level insulating film 40. The wiring 42 is formed to extend over the write word line 37 from above the wiring 38 and is electrically connected to the wiring 38 via a metal plug 43 buried in the contact hole 41 formed in the inter-level insulating film 40.

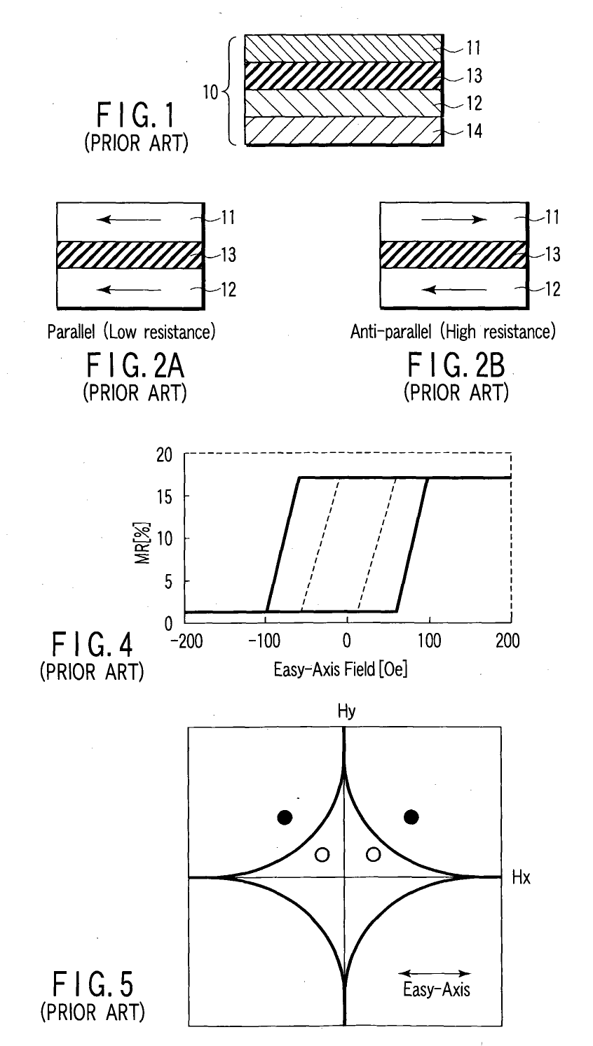

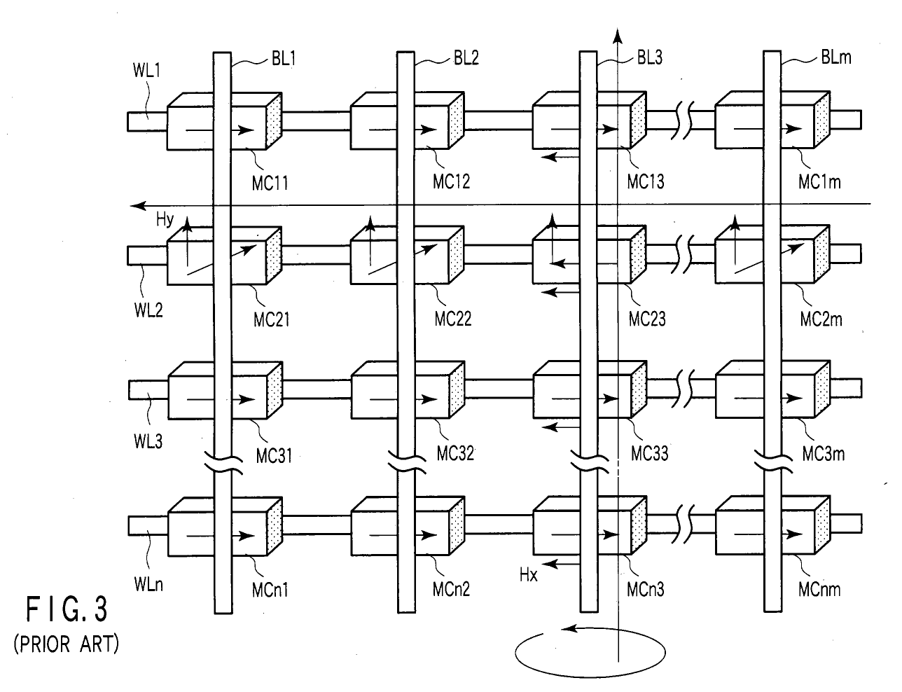

A fourth inter-level insulating film 44 is formed on the third inter-level insulating film 40 and wiring 42. A TMR element 10 is formed on the wiring 42 in a portion of the inter-level insulating film 44 which lies above the write word line 37. As shown in FIG. 1, the TMR element 10 has a structure which has the insulating layer (tunnel barrier) 13 sandwiched between the two ferromagnetic layers (memory layer and pinned layer) 11, 12 and the anti-ferromagnetic layer 14 is disposed as a fixing layer on one of the two ferromagnetic layers 11, 12. In this case, the spin direction of the TMR element 10 can be set perpendicular to or parallel to the drawing.

A bit line (read/write bit line) 45 which is formed of a fourth-layered metal layer is formed on the inter-level insulating film 40 and TMR element 10 to extend in a direction which intersects the write word line 37 and read word line 27.

The memory cell with the above structure is basically formed by use of an existing CMOS process.

With the above structure, the write word line 37 and bit line 45 are used as write wirings to generate a magnetic field so as to change the spin direction according to write data at the data write time. On the other hand, at the read time, the MOSFET Tr which is a switching element is set into the ON state by use of the read word line 27 so as to permit a current to flow from the bit line 45 to the source line 31 via the TMR element 10 and MOSFET Tr.

At this time, in the present embodiment, potential of the node N of the sense amplifier 50 is set higher than Vh by a voltage drop due to the sum of the ON resistance of the column selection gate and the ON resistance of the MOSFET Tr. As a result, voltage applied across the series circuit of the MOSFET Tr and TMR element 10 is set higher than Vh by a voltage drop due to the ON resistance of the MOSFET Tr. Therefore, voltage applied across the TMR element 10 becomes equal to Vh.

Next, the definition of Vh is explained. Generally, it is known that the MR ratio of the TMR element 10 becomes lower as voltage applied across the TMR element 10 becomes higher. It is assumed that application voltage which sets the MR ratio to half that obtained when application voltage is 0 V is Vh.

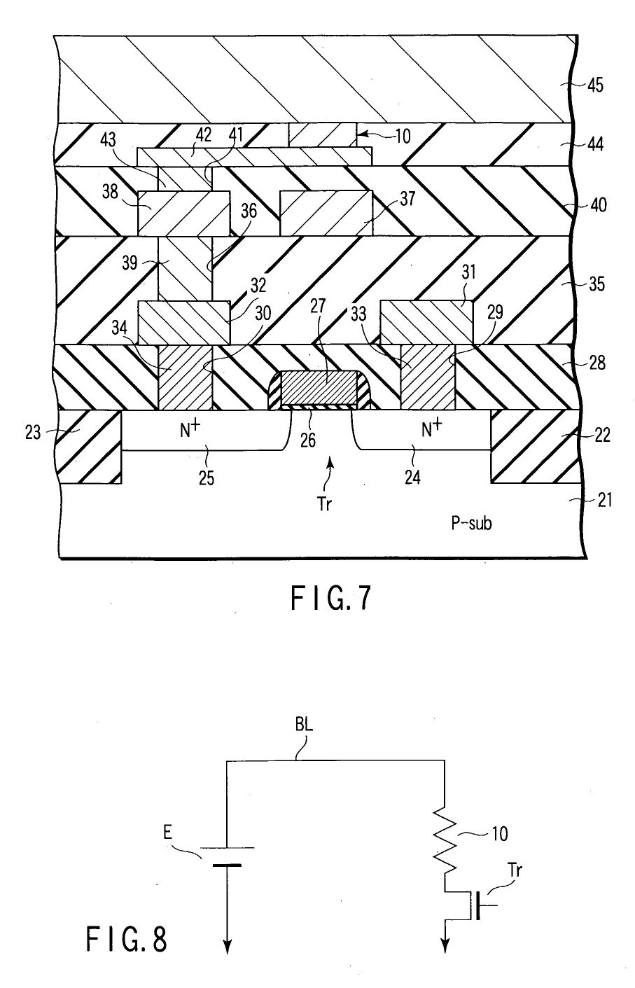

The equivalent circuit at the read time in the one-MOSFET/one-TMR type MRAM as shown in FIGS. 6 and 7 is obtained as shown in FIG. 8, for example. It seems that a current flowing through the TMR element 10 and MOSFET Tr can be increased if the read voltage E is set higher. However, as described before, since there occurs a phenomenon that the MR ratio is lowered if the read voltage E is increased, a read signal amount has a local maximum value with respect to the read voltage E. That is, since the MR ratio is substantially linearly deteriorates with an increase in the read voltage E, the relation of MR=MR_max-kxE can be attained. In this case, assume that the resistance R of an MTJ (Magnetic Tunnel Junction) does not depend on the application voltage. Then, the following equations can be obtained.

$$\begin{matrix}Δ I = E / R - E / ( R [ 1 + MR ] ) \\ = E / R \times MR / ( 1 + MR ) ⅆ ( Δ I ) / ⅆ E \\ = 1 / R \times MR / ( 1 + MR ) + E / R \times 1 / {( 1 + MR )}^{2} \times ⅆ ( MR ) / ⅆ E \\ = 1 / R \times 1 / {( 1 + MR )}^{2} \times [ MR ( 1 + MR ) - k \times E ] \\ = 1 / R \times 1 / {( 1 + MR )}^{2} \times [ m + \sqrt{m} - k \times E ] [ m - \sqrt{m} - k \times E ]\end{matrix}$$

where m=1+MR_max

ΔI is set to a local maximum value at the time of V=(m−\sqrt{m})/k and is set to a local minimum value at the time of E=(m+\sqrt{m})/k. Since V does not exceed MR_max/k, ΔI is set to a maximum value at the time of E=(m−\sqrt{m})/k. Since m is smaller than 1, \sqrt{m} can be approximated as follows.
\sqrt{m}=1+MR_max/2

Therefore, the maximum value of ΔI can be obtained when the following equation is established.

$$\begin{matrix}E = ( m - \sqrt{m} ) / k \\ = ( 1 + MR\_max - [ 1 + MR\_max / 2 ] ) / k \\ = 1 + MR\_max / 2 k\end{matrix}$$

Further, the following equation can be attained based on the definition of Vh.
MR_max/2=MR_max−kxVh

Therefore, since the relation of Vh=MR_max/2k can be attained, ΔI is set to the maximum value when E is approximately equal to Vh.

As a result, the read margin in the one-MOSFET/one-TMR type MRAM can be set to maximum by setting the read voltage E applied to the memory cell from the read circuit which causes the resistance variation rate obtained when the voltage applied across the TMR element 10 is 0 V to be set equal to half the resistance variation rate obtained when the TMR element is changed from the low-resistance state to the high-resistance state.

In the first embodiment, a case wherein the MOSFET is used as a switching element in the memory cell is explained, but it is of course possible to use a different switching element such as a bipolar transistor. When bipolar transistors are used, the base electrodes of the bipolar transistors on the same row are connected to a corresponding one of the read word lines WL1 to WLn, the emitter electrodes (or collector electrodes) thereof are connected to the source line, and the collector electrodes (or emitter electrodes) are connected to one-side ends of the TMR elements 10.

[Second Embodiment]

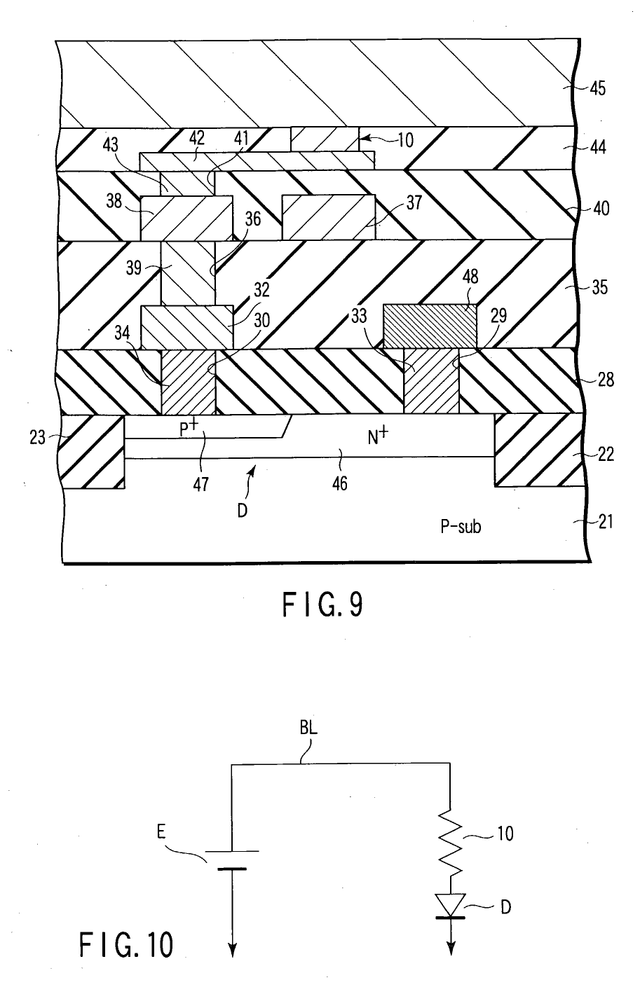

In the present embodiment, the MOSFET Tr in the first embodiment is replaced by a diode D. That is, diodes D are provided instead of the MOSFETs Tr in the respective memory cells MC11 to MCnm in the circuit of FIG. 6, the anodes of the diodes are connected to one-side ends of the TMR elements 10 and the cathodes thereof on the same row are connected to a corresponding one of the word lines WL1 to WLn. FIG. 9 shows an example of the structure of a memory cell in a one-diode/one-TMR type MRAM. The memory cell is called a cross point type memory cell. FIG. 10 shows an equivalent circuit at the read time in this embodiment.

In the memory cell section of this structure, STI regions 22, 23 are formed on the main surface of a P-type silicon substrate 21 to isolate element regions. An N⁺-type impurity diffusion region 46 used as the cathode region of diode D is formed on the main surface of the silicon substrate 21 isolated by the STI regions 22, 23. A P⁺-type impurity diffusion region 47 used as the anode region of the diode D is formed in part of the cathode region 46. A first inter-level insulating film 28 is formed on the silicon substrate 21. Contact holes 29, 30 are formed in portions of the inter-level insulating film 28 which lie on the cathode region 46 and anode region 47.

A word line 48 and wiring 32 which are formed of a first-layered metal layer are formed on the inter-level insulating film 28. The word line 48 is electrically connected to the cathode region 46 via a metal plug 33 formed in the contact hole 29 and the wiring 32 is electrically connected to the anode region 47 via a metal plug 34 formed in the contact hole 30.

A second inter-level insulating film 35 is formed on the inter-level insulating film 28, word line 48 and wiring 32. A contact hole 36 is formed in a portion of the inter-level insulating film 35 which lies on the wiring 32. A write word line 37 and wiring 38 which are formed of a second-layered metal layer are formed on the inter-level insulating film 35. The write word line 37 is formed to extend in the same direction as the word line 48. Further, the wiring 38 is formed above the wiring 32 and is electrically connected to the wiring 32 via a metal plug 39 buried in the contact hole 36.

A third inter-level insulating film 40 is formed on the second inter-level insulating film 35, write word line 37 and wiring 38. A contact hole 41 is formed in a portion of the inter-level insulating film 40 which lies on the wiring 38. A wiring 42 which is formed of a third-layered metal layer is formed on the inter-level insulating film 40. The wiring 42 is formed to extend over the write word line 37 from above the wiring 38 and is electrically connected to the wiring 38 via a metal plug 43 buried in the contact hole 41 formed in the inter-level insulating film 40.

A fourth inter-level insulating film 44 is formed on the third inter-level insulating film 40 and wiring 42. A TMR element 10 is formed on the wiring 42 in a portion of the inter-level insulating film 44 which lies above the write word line 37. As shown in FIG. 1, the TMR element 10 has a structure which has the insulating layer (tunnel barrier) 13 sandwiched between the two ferromagnetic layers (memory layer and pinned layer) 11, 12 and the anti-ferromagnetic layer 14 is disposed as a fixing layer on one of the two ferromagnetic layers 11, 12. In this case, the spin direction of the TMR element 10 can be set perpendicular to or parallel to the drawing.

A bit line (read/write bit line) 45 which is formed of a fourth-layered metal layer is formed on the inter-level insulating film 44 and TMR element 10 to extend in a direction which intersects the write word line 37.

With the above structure, the write/read operation is performed by use of two wirings including the word line 48 and bit line 45. At this time, in order to perform the write/read operation with respect only to a selected cell by use of rectification of the diode D, bias voltages applied to the respective wirings are controlled.

Then, as in the first embodiment, at the data read time, voltage applied across the TMR element 10 is set substantially equal to Vh. In order to serve the above purpose, potential of the node N of the sense amplifier 50 is set higher than Vh by the sum of a voltage drop due to the ON resistance of the column selection gate CSG and a voltage drop due to the forward voltage of the diode D. As a result, voltage applied across the series circuit of the diode D and TMR element 10 is set higher than Vh by the forward voltage of the diode D.

With the above configuration, the read margin can be made large in the one-diode/one-TMR type MRAM using the diode as the selection element of the TMR element 10.

In the first and second embodiments, it is possible to configure the memory cells MC11 to MCnm by connecting a plurality of TMR elements in series or in parallel to commonly use one selection element (MOSFET, bipolar transistor, diode). All of the plurality of TMR elements can be connected in series or in parallel, but at least two of the TMR elements can be connected in series or in parallel.

[Third Embodiment]

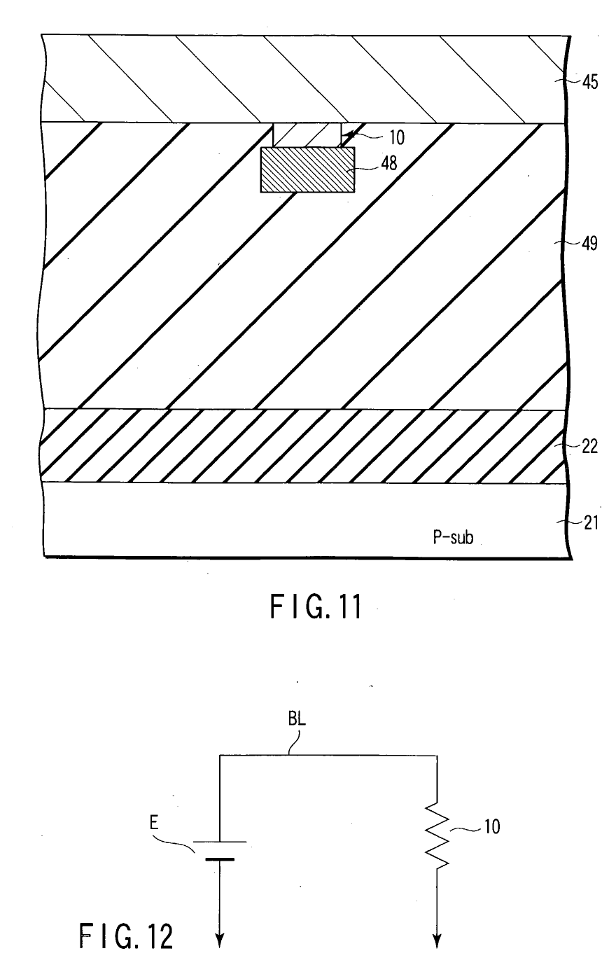

The present embodiment relates to a cross point type cell which does not require a selection element (MOSFET, bipolar transistor, diode or the like) as in the first and second embodiments. FIG. 11 shows the cell structure of the cell. FIG. 12 shows an equivalent circuit at the read time in the present embodiment.

That is, an STI region 22 is formed on the main surface of a P-type silicon substrate (P-sub) 21. An inter-level insulating film 49 is formed on the STI region 22 and silicon substrate 21. A word line 48 is buried in the inter-level insulating film 49 and a TMR element 10 is formed on the word line 48. As shown in FIG. 1, the TMR element 10 has a structure which has the insulating layer (tunnel barrier) 13 sandwiched between the two ferromagnetic layers (memory layer and pinned layer) 11, 12 and the anti-ferromagnetic layer 14 is disposed as a fixing layer on one of the two ferromagnetic layers 11, 12. In this case, the spin direction of the TMR element 10 can be set perpendicular to or parallel to the drawing.

A bit line (read/write bit line) 45 which is formed of a metal layer is formed on the inter-level insulating film 49 and TMR element 10 to extend in a direction which intersects the word line 48.

With the above type of memory cell, the read/write operation is performed only by use of two wirings of the word line 48 and bit line 45. Therefore, a current flows in cells other than the selected cell. Thus, it is necessary to think out a device for the circuit operation.

With the above configuration, in the cross point type MRAM having no selection element, the read margin can be made large.

In the third embodiment, the word line 48 is disposed below the TMR element 10 and the bit line 45 is disposed above the TMR element 10, but it is of course possible to dispose the word line 48 above the TMR element 10 and dispose the bit line 45 below the TMR element 10.

[Fourth Embodiment]

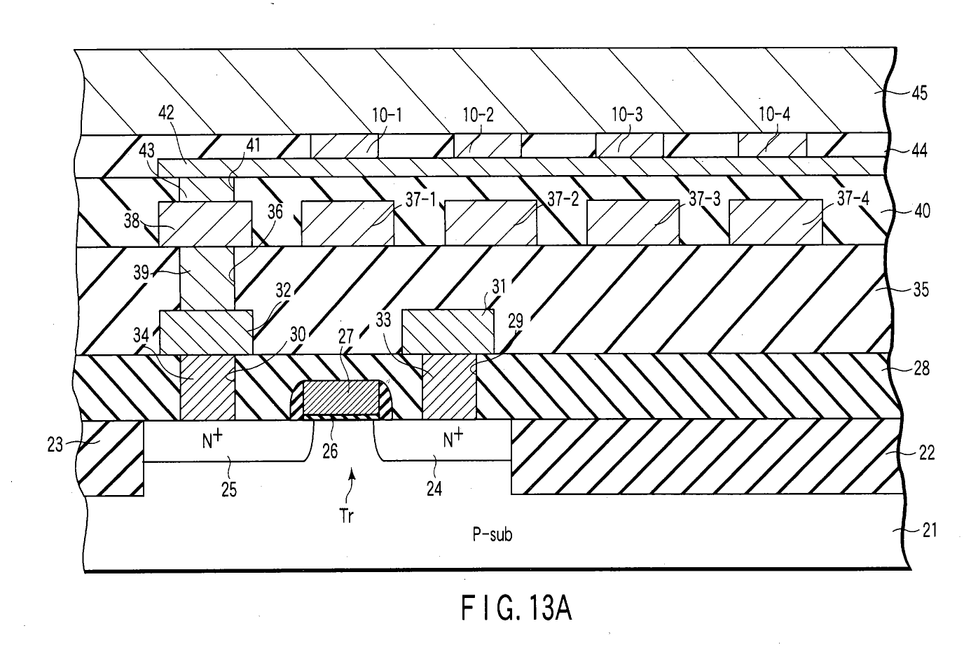

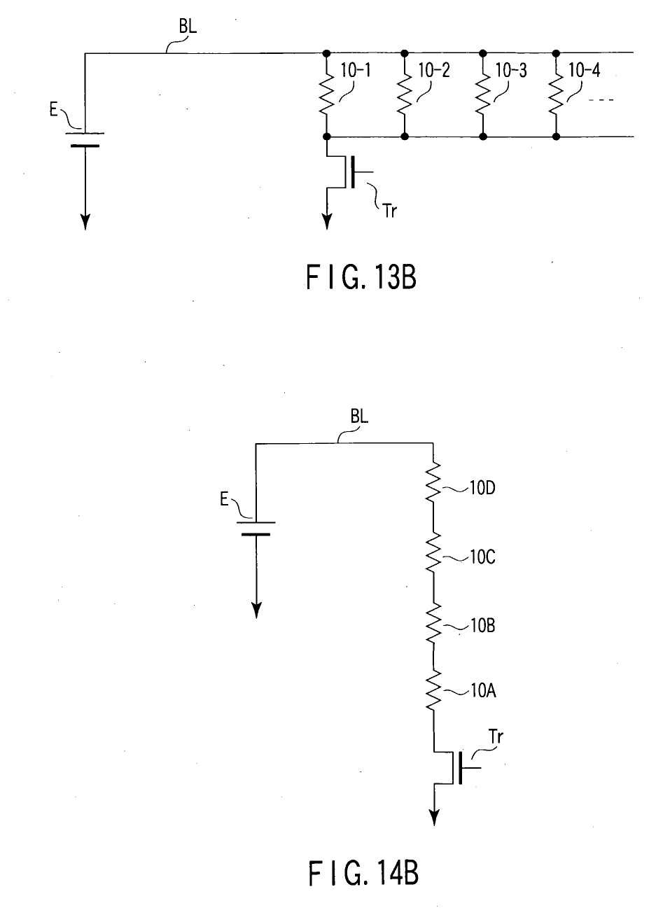

FIG. 13A is a cross-sectional view showing an example of the structure of each memory cell of a memory cell array, for illustrating a magnetic random access memory according to a fourth embodiment of this invention. FIG. 13B is a circuit diagram showing an equivalent circuit at the read time in this embodiment. The memory cell is called a ladder type cell. The basic structure of a switch element (MOSFET) Tr is the same as that of FIG. 7 and TMR elements 10-1, 10-2, . . . are connected in parallel and arranged between the drain of the MOSFET Tr and a read bit line BL.

That is, STI regions 22, 23 are formed on the main surface of a P-type silicon substrate (P-sub) 21 to isolate element regions. N⁺-type impurity diffusion regions 24, 25 used as source, drain regions of a MOSFET Tr are formed on the main surface of the silicon substrate 21 isolated by the STI regions 22, 23. A gate insulating film 26 is formed on that part of the substrate 21 which lies between the source and drain regions 24 and 25 and a gate electrode 27 is formed on the gate insulating film 26. A first inter-level insulating film 28 is formed on the silicon substrate 21 and gate electrode 27. Contact holes 29, 30 are formed in portions of the inter-level insulating film 28 which lie on the source, drain regions 24, 25.

A source line (common ground line) 31 and wiring 32 which are formed of a first-layered metal layer are formed on the inter-level insulating film 28. The source line 31 is electrically connected to the source region 24 via a metal plug 33 formed in the contact hole 29. The wiring 32 is electrically connected to the drain region 25 via a metal plug 34 formed in the contact hole 30.

A second inter-level insulating film 35 is formed on the inter-level insulating film 28, source line 31 and wiring 32. A contact hole 36 is formed in a portion of the inter-level insulating film 35 which lies on the wiring 32. Write word lines 37-1, 37-2, . . . and wiring 38 which are formed of a second-layered metal layer are formed on the inter-level insulating film 35. The write word lines 37-1, 37-2, . . . are formed to extend in the same direction as the gate electrode 27. Further, the wiring 38 is formed in a position above the wiring 32 and is electrically connected to the wiring 32 via a metal plug 39 buried in the contact hole 36.

A third inter-level insulating film 40 is formed on the second inter-level insulating film 35, write word lines 37-1, 37-2, . . . and wiring 38. A contact hole 41 is formed in a portion of the inter-level insulating film 40 which lies on the wiring 38. A lower lead wiring 42 which is formed of a third-layered metal layer is formed on the inter-level insulating film 40. The lower lead wiring 42 is formed to extend over the write word lines 37-1, 37-2, . . . from above the wiring layer 38 and is electrically connected to the wiring 38 via a metal plug 43 buried in the contact hole 41 formed in the inter-level insulating film 40.

A fourth inter-level insulating film 44 is formed on the third inter-level insulating film 40 and lower lead wiring 42. TMR elements 10-1, 10-2, . . . are formed on the wiring 42 in portions of the inter-level insulating film 44 which lie above the write word lines 37-1, 37-2, . . . As shown in FIG. 1, each of the TMR elements 10-1, 10-2, . . . has a structure which has the insulating layer (tunnel barrier) 13 sandwiched between the two ferromagnetic layers (memory layer and pinned layer) 11, 12. Further, the anti-ferromagnetic layer 14 is disposed as a fixing layer on one of the two ferromagnetic layers 11, 12. In this case, the spin direction of each of the TMR elements 10-1, 10-2, . . . can be set perpendicular to or parallel to the drawing.

A read/write bit line 45 which is formed of a fourth-layered metal layer is formed on the inter-level insulating film 44 and TMR elements 10-1, 10-2, . . . to extend in a direction which intersects the write word lines 37-1, 37-2, . . . and selection gate 27. The TMR elements 10-1, 10-2, . . . are connected in parallel between the lower lead wiring 42 and the write/read bit line 45.

The memory cell with the above structure is basically formed by use of an existing CMOS process.

With the above structure, the write word lines 37-1, 37-2, . . . and write/read bit line 45 are used to generate a magnetic field so as to change the spin direction of a selected TMR element or TMR elements among the TMR elements 10-1, 10-2, . . . according to write data at the data write time.

On the other hand, at the read time, the MOSFET Tr which is a switching element is set into the ON state by applying voltage to the gate electrode (selection gate line) 27 so as to permit a current to flow from the write/read bit line 45 to the source line 31 via the TMR elements 10-1, 10-2, . . . and the current path of the MOSFET Tr. The current flowing at this time is stored as a reference value. Then, information of “1” or “0” is written by use of the write/read bit line 45 and a write word line corresponding to a TMR element from which data is desired to be read. Next, voltage is applied to the gate electrode (selection gate line) 27 again to set the MOSFET Tr into the ON state so as to permit a current to flow from the write/read bit line 45 to the source line 31 via the TMR elements 10-1, 10-2, . . . and the current path of the MOSFET Tr. The current value obtained at this time is compared with the current value stored as the reference value. If the result of comparison indicates coincidence of the compared values, the stored data is the same as the written data. If the result of comparison indicates non-coincidence, the written data is different from the stored data. Thus, the stored data can be determined and data can be read.

At this time, in the present embodiment, potential of the node N of the sense amplifier 50 is set higher than Vh by voltage drops due to the ON resistance of the column selection gate CSG, the ON resistance of the MOSFET Tr and the parallel-connected TMR elements 10-1, 10-2, . . . As a result, voltage applied across the series circuit of the MOSFET Tr and TMR elements 10-1, 10-2, . . . is set higher than Vh by a voltage drop due to the ON resistance of the MOSFET Tr. Therefore, voltage applied across the TMR elements 10-1, 10-2, . . . becomes equal to Vh.

[Fifth Embodiment]

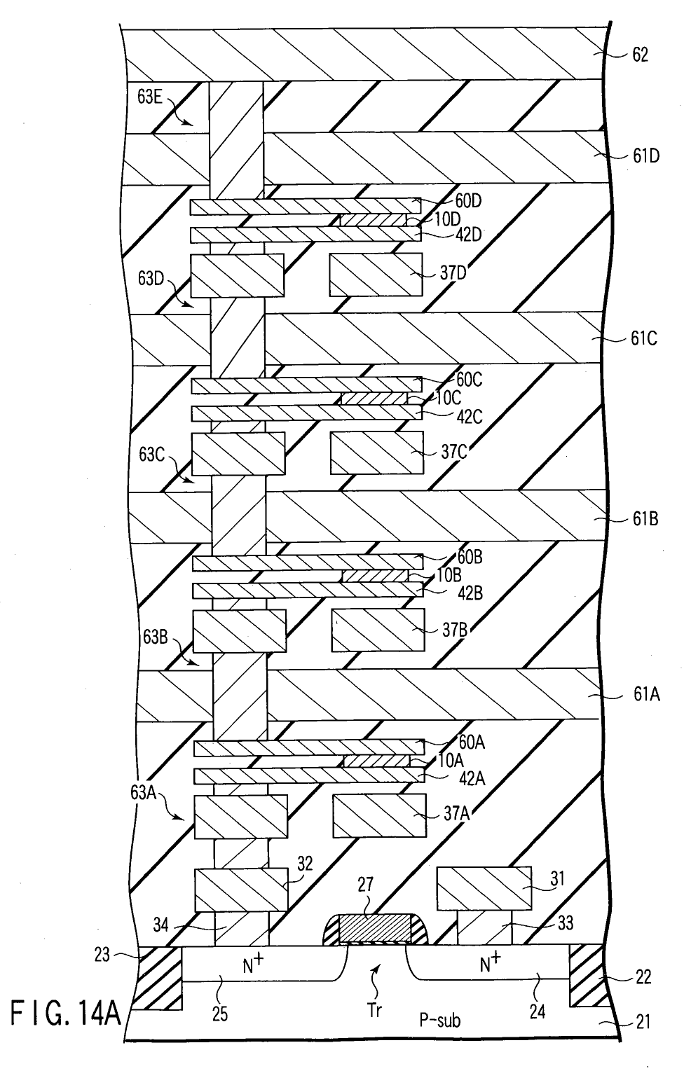

FIG. 14A is a cross-sectional view showing an example of the structure of each memory cell of a memory cell array, for illustrating a magnetic random access memory according to a fifth embodiment of this invention. The memory cell is basically obtained by stacking a plurality of memory cells on the memory cell shown in FIG. 7 and is called a stacked type cell. FIG. 14B shows an equivalent circuit at the read time in the present embodiment. TMR elements 10A, 10B, 10C, 10D are serially connected and arranged between the drain of a MOSFET Tr and a read bit line BL.

In FIG. 14A, portions which are the same as those of FIG. 7 are denoted by the same reference symbols and the detail explanation thereof is omitted.

A write word line 37A formed of a second-layered metal wiring, a third-layered metal wiring 42A, the TMR element 10A, a fourth-layered metal wiring 60A, a write bit line 61A formed of a fifth-layered metal wiring, a write word line 37B formed of a sixth-layered metal wiring, a seventh-layered metal wiring 42B, the TMR element 10B, an eighth-layered metal wiring 60B, a write bit line 61B formed of a ninth-layered metal wiring, a write word line 37C formed of a tenth-layered metal wiring, an eleventh-layered metal wiring 42C, the TMR element 10C, a twelfth-layered metal wiring 60C, a write bit line 61C formed of a thirteenth-layered metal wiring, a write word line 37D formed of a fourteenth-layered metal wiring, a fifteenth-layered metal wiring 42D, the TMR element 10D, a sixteenth-layered metal wiring 60D, a write bit line 61D formed of a seventeenth-layered metal wiring, and a read bit line 62 formed of an eighteenth-layered metal wiring are sequentially laminated via inter-level insulating films above a read word line 27 used as the gate electrode of the MOSFET Tr.

The TMR element 10A is sandwiched between the third-layered metal wiring 42A and the fourth-layered metal wiring 60A and is electrically connected to the wirings 42A, 60A. The TMR element 10B is sandwiched between the seventh-layered metal wiring 42B and the eighth-layered metal wiring 60B and is electrically connected to the wirings 42B, 60B. The TMR element 10C is sandwiched between the eleventh-layered metal wiring 42C and the twelfth-layered metal wiring 60C and is electrically connected to the wirings 42C, 60C. The TMR element 10D is sandwiched between the fifteenth-layered metal wiring 42D and the sixteenth-layered metal wiring 60D and is electrically connected to the wirings 42D, 60D.

The third-layered metal wiring 42A is electrically connected to the drain of the MOSFET Tr via a contact 63A. The fourth-layered metal wiring 60A is electrically connected to the seventh-layered metal wiring 42B via a contact 63B. The eighth-layered metal wiring 60B is electrically connected to the eleventh-layered metal wiring 42C via a contact 63C. The twelfth-layered metal wiring 60C is electrically connected to the fifteenth-layered metal wiring 42D via a contact 63D. The sixteenth-layered metal wiring 60D is electrically connected to the read bit line 62 formed of the eighteenth-layered metal wiring via a contact 63E.

The memory cell with the above structure is basically formed by use of an existing CMOS process.

With the above structure, the write word lines 37A, 37B, 37C, 37D and write bit lines 61A, 61B, 61C, 61D are used to apply a magnetic field to a selected TMR element or TMR elements among the TMR elements 10A, 10B, 10C, 10D and change the spin direction according to write data at the data write time.

On the other hand, at the read time, the MOSFET Tr which is a switching element is set into the ON state by applying voltage to the gate electrode (selection gate line) 27. Thus, a current is caused to flow from the read bit line 62 to the source line 31 via the contact 63E, wiring 60D, TMR element 10D, wiring 42D, contact 63D, wiring 60C, TMR element 10C, wiring 42C, contact 63C, wiring 60B, TMR element 10B, wiring 42B, contact 63B, wiring 60A, TMR element 10A, wiring 42A, contact 63A and the current path of the MOSFET Tr. Then, the current flowing at this time is stored as a reference value. Next, information of “1” or “0” is written into the TMR element by use of the write bit line and a write word line corresponding to the TMR element which is to be subjected to the read process. After this, voltage is applied to the gate electrode (selection gate line) 27 again to set the MOSFET Tr into the ON state. Thus, a current is caused to flow from the read bit line 62 to the source line 31 via the contacts 60E to 60A, TMR elements 10D to 10A and the current path of the MOSFET Tr. The current value obtained at this time is compared with the current value stored as the reference value. If the result of comparison indicates coincidence of the compared values, the stored data is the same as the written data. If the result of comparison indicates non-coincidence, the written data is different from the stored data. Thus, the stored data can be determined based on the result of comparison and data can be read.

At this time, like the above embodiments, potential of the node N of the sense amplifier 50 is set higher than Vh by voltage drops due to the ON resistance of the column selection gate CSG, the ON resistance of the MOSFET Tr and the series-connected TMR elements 10A to 10D. As a result, voltage applied across the series circuit of the MOSFET Tr and TMR elements 10A to 10D is set higher than Vh by a voltage drop due to the ON resistance of the MOSFET Tr. Therefore, voltage applied across the series-connected TMR elements 10A to 10D becomes equal to Vh.

[Sixth Embodiment]

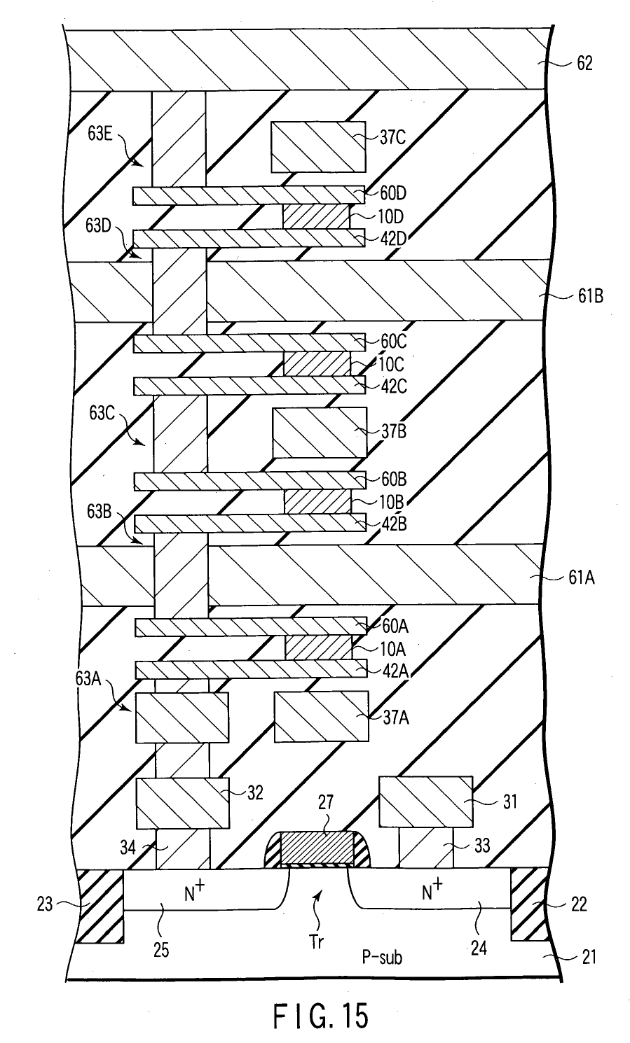

FIG. 15 is a cross-sectional view showing an example of the structure of each memory cell of a memory cell array, for illustrating a magnetic random access memory according to a sixth embodiment of this invention. Like the memory cell shown in FIG. 14A, the memory cell is called a stacked type cell. The present embodiment is similar to the fifth embodiment in that four TMR elements 10A, 10B, 10C, 10D are stacked. In the present embodiment, the number of laminated metal wirings is reduced by causing a plurality of TMR elements arranged in the upper and lower layers to commonly use the write word lines and write bit lines.

That is, the lower layer portion with respect to a write bit line 61A formed of a fifth-layered metal wiring has the same structure as that of FIG. 14A. The upper layer portion with respect to the write bit line 61A is formed by sequentially laminating a sixth-layered metal wiring 42B, the TMR element 10B, a seventh-layered metal wiring 60B, a write word line 37B formed of an eighth-layered metal wiring, a ninth-layered metal wiring 42C, the TMR element 10C, a tenth-layered metal wiring 60C, a write bit line 61B formed of an eleventh-layered metal wiring, a twelfth-layered metal wiring 42D, the TMR element 10D, a thirteenth-layered metal wiring 60D, a write word line 37C formed of a fourteenth-layered metal wiring and a read bit line 62 formed of a fifteenth-layered metal wiring via inter-level insulating films.

The equivalent circuit of the memory cell of the present embodiment is the same as that of FIG. 14B and is different in that the write bit line 61A is commonly used by the TMR elements 10A, 10B, the write word line 37B is commonly used by the TMR elements 10B, 10C, and the write bit line 61B is commonly used by the TMR elements 10C, 10D to perform the write operation. The other basic read/write operation is the same as that of the fifth embodiment.

According to the above configuration, the number of laminated metal wiring layers can be reduced.

[Seventh Embodiment]

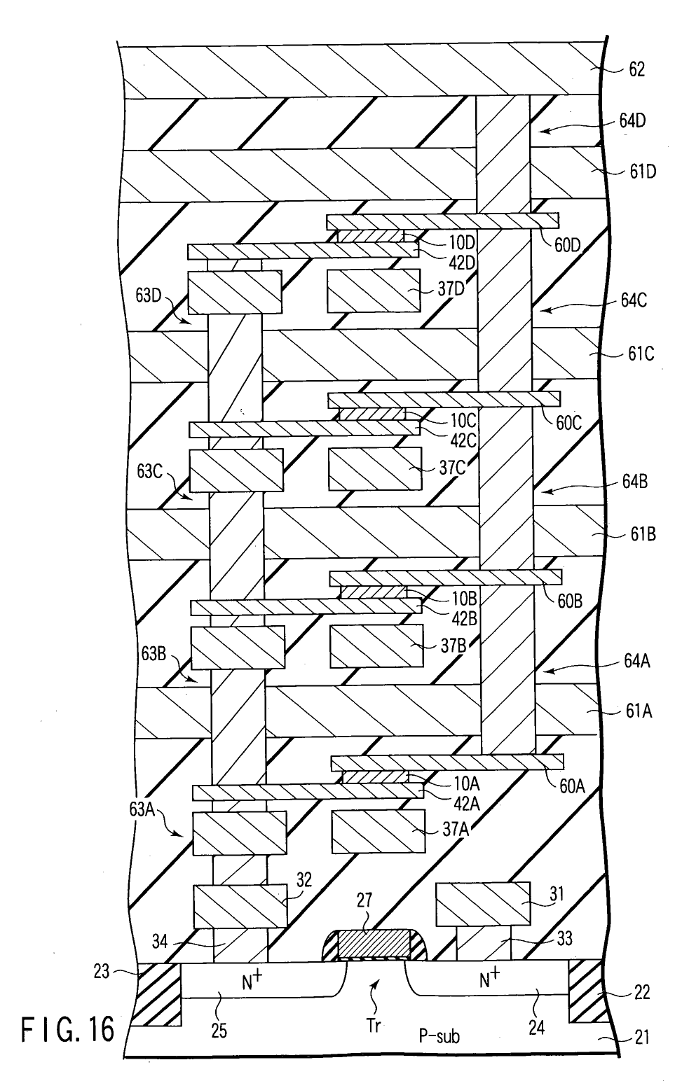

FIG. 16 is a cross-sectional view showing an example of the structure of each memory cell of a memory cell array, for illustrating a magnetic random access memory according to a seventh embodiment of this invention. Like the cases of FIGS. 14A and 15, the memory cell is called a stacked type cell. The present embodiment is similar to the fifth and sixth embodiments in that four TMR elements 10A to 10D are stacked. In the present embodiment, the TMR elements 10A to 10D are connected in parallel between a read bit line 62 and the drain of a MOSFET Tr.

That is, a third-layered metal wiring 42A, seventh-layered metal wiring 42B, eleventh-layered metal wiring 42C and fifteenth-layered metal wiring 42D are commonly connected via contacts 63A, 63B, 63C, 63D and a fourth-layered metal wiring 60A, eighth-layered metal wiring 60B, twelfth-layered metal wiring 60C and sixteenth-layered metal wiring 60D are commonly connected via contacts 64A, 64B, 64C. The contact 63A is electrically connected to the drain of the MOSFET Tr and the metal wiring 60D is connected to the read bit line 62 via the contact 63D.

With the above configuration, the data write/read operation is basically the same as that of the memory cells shown in FIGS. 13A, 14A and 15.

Further, potential of the node N of the sense amplifier 50 is set higher than Vh by voltage drops due to the ON resistance of the column selection gate CSG, the ON resistance of the MOSFET Tr and the parallel-connected TMR elements 10A to 10D. As a result, voltage applied across the series circuit of the MOSFET Tr and TMR elements 10A to 10D is set higher than Vh by a voltage drop due to the ON resistance of the MOSFET Tr. Therefore, voltage applied across the TMR elements 10A to 10D becomes equal to Vh.

[Eighth Embodiment]

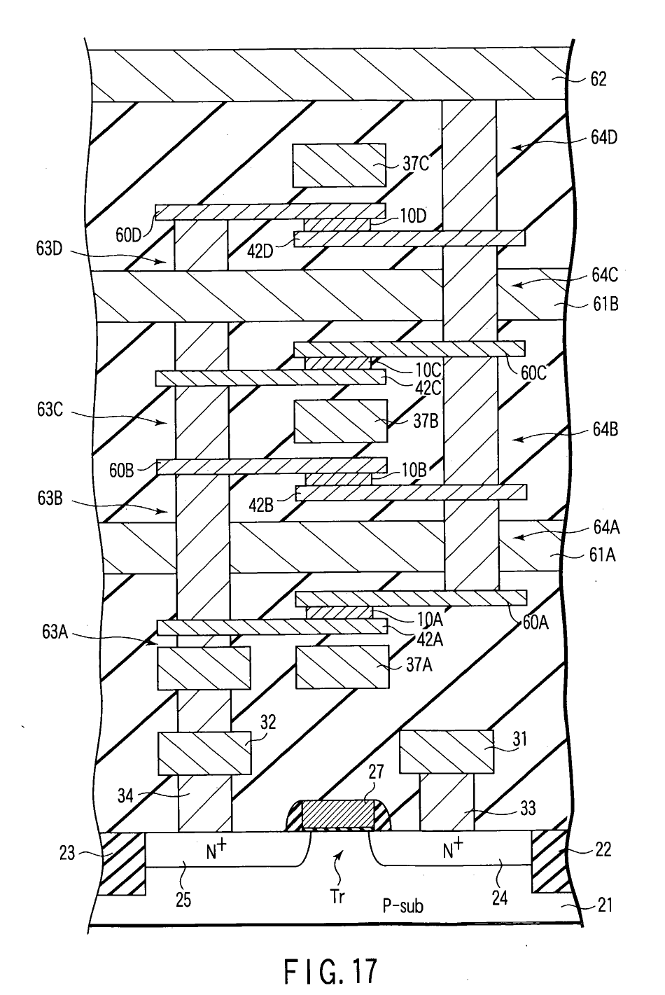

FIG. 17 is a cross-sectional view showing an example of the structure of each memory cell of a memory cell array, for illustrating a magnetic random access memory according to an eighth embodiment of this invention. Like the cases of FIGS. 14A, 15 and 16, the memory cell is called a stacked type cell. The present embodiment is similar to the fifth to seventh embodiments in that four TMR elements 10A to 10D are stacked. In the present embodiment, in the structure shown in FIG. 16, the write word line and write bit line shown in FIG. 15 are commonly used by a plurality of TMR elements. Also, in this structure, the TMR elements 10A to 10D are connected in parallel between a read bit line 62 and the drain of a MOSFET Tr.

That is, metal wirings 42A, 60B, 42C, 60D are commonly connected via contacts 63A, 63B, 63C, 63D and metal wirings 60A, 42B, 60C, 42D are commonly connected via contacts 64A, 64B, 64C. The contact 63A is connected to the drain of the MOSFET Tr and the metal wiring 42D is connected to the read bit line 62 via the contact 63D.

With the above configuration, the data write/read operation is basically the same as that of the memory cells shown in FIGS. 13A, 14A, 15 and 16.

Further, potential of the node N of the sense amplifier 50 is set higher than Vh by a voltage drop due to the sum of the ON resistance of the column selection gate CSG and the ON resistance of the MOSFET Tr. Therefore, voltage applied across the series circuit of the MOSFET Tr and TMR elements 10A to 10D is set higher than Vh by a voltage drop due to the ON resistance of the MOSFET Tr. As a result, voltage applied across the TMR elements 10A to 10D becomes equal to Vh.

[Ninth Embodiment]

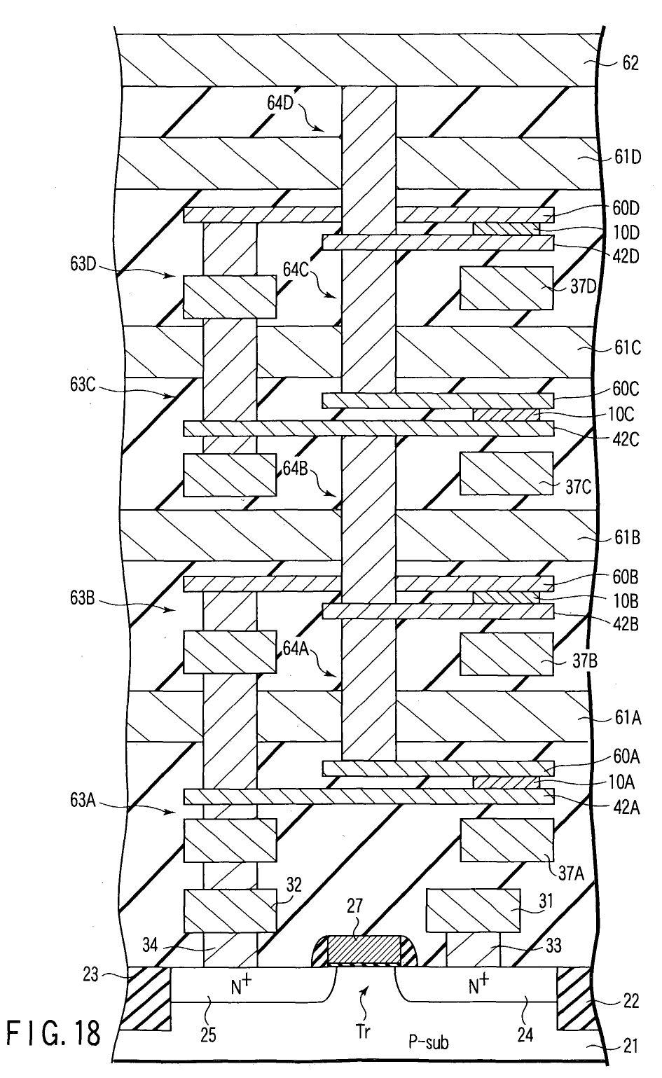

FIG. 18 is a cross-sectional view showing an example of the structure of each memory cell of a memory cell array, for illustrating a magnetic random access memory according to a ninth embodiment of this invention. Like the cases of FIGS. 14A, 15 to 17, the memory cell is called a stacked type cell. The present embodiment is similar to the fifth to eighth embodiments in that four TMR elements 10A to 10D are stacked. In the present embodiment, the TMR elements 10A to 10D are connected in a series-parallel fashion between a read bit line 62 and the drain of a MOSFET Tr.

That is, metal wirings 42A, 60B are commonly connected via contacts 63A, 63B and metal wirings 60A, 42B, 42C are commonly connected via contacts 64A, 64B. Further, metal wirings 42C, 60D are commonly connected via contacts 63C, 63D and metal wirings 60C, 42D are commonly connected via contact 64C. The contact 63A is connected to the drain of the MOSFET Tr and the metal wiring 42D is connected to the read bit line 62 via the contact 63D.

With the above configuration, the data write/read operation is basically the same as that of the memory cells shown in FIGS. 13A, 14A, 15 to 17.

Further, potential of the node N of the sense amplifier 50 is set higher than Vh by a voltage drop due to the sum of the ON resistance of the column selection gate CSG and the ON resistance of the MOSFET Tr. Therefore, voltage applied across the series-parallel circuit of the MOSFET Tr and TMR elements 10A to 10D is set higher than Vh by a voltage drop due to the ON resistance of the MOSFET Tr. As a result, voltage applied across the TMR elements 10A to 10D becomes equal to Vh.

[Tenth Embodiment]

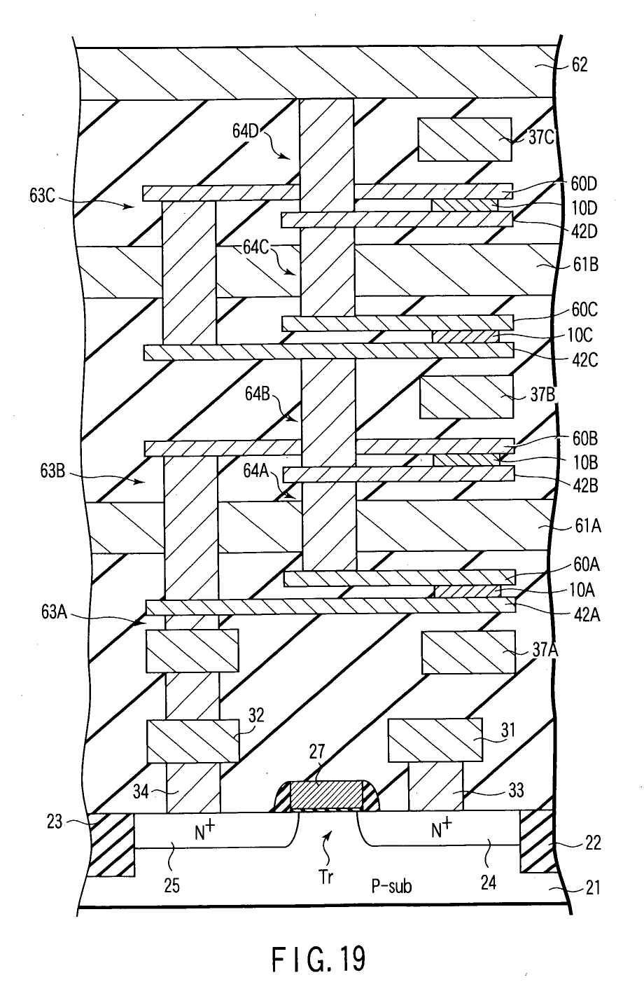

FIG. 19 is a cross-sectional view showing an example of the structure of each memory cell of a memory cell array, for illustrating a magnetic random access memory according to a tenth embodiment of this invention. Like the cases of FIGS. 14A, 15 to 18, the memory cell is called a stacked type cell. The present embodiment is similar to the fifth to ninth embodiments in that four TMR elements 10A to 10D are stacked. In the present embodiment, like the case of the ninth embodiment, the TMR elements 10A to 10D are connected in a series-parallel fashion between a read bit line 62 and the drain of a MOSFET Tr.

That is, metal wirings 42A, 60B shown in FIG. 17 are commonly connected via a contact 63B and metal wirings 60A, 42B, 42C are commonly connected via contacts 64A, 64B. Further, metal wirings 42C, 60D are commonly connected via a contact 63C and metal wirings 60C, 42D are commonly connected via a contact 64C. The metal wiring 42A is connected to the drain of the MOSFET Tr via a contact 63A and the metal wiring 42D is connected to the read bit line 62 via a contact 63D.

With the above configuration, the data write/read operation is basically the same as that of the memory cells shown in FIGS. 13A, 14A, 15 to 18.

Further, potential of the node N of the sense amplifier 50 is set higher than Vh by a voltage drop due to the sum of the ON resistance of the column selection gate CSG and the ON resistance of the MOSFET Tr. Therefore, voltage applied across the series circuit of the MOSFET Tr and TMR elements 10A to 10D is set higher than Vh by a voltage drop due to the ON resistance of the MOSFET Tr. As a result, voltage applied across the TMR elements 10A to 10D becomes equal to Vh.

[Eleventh Embodiment]

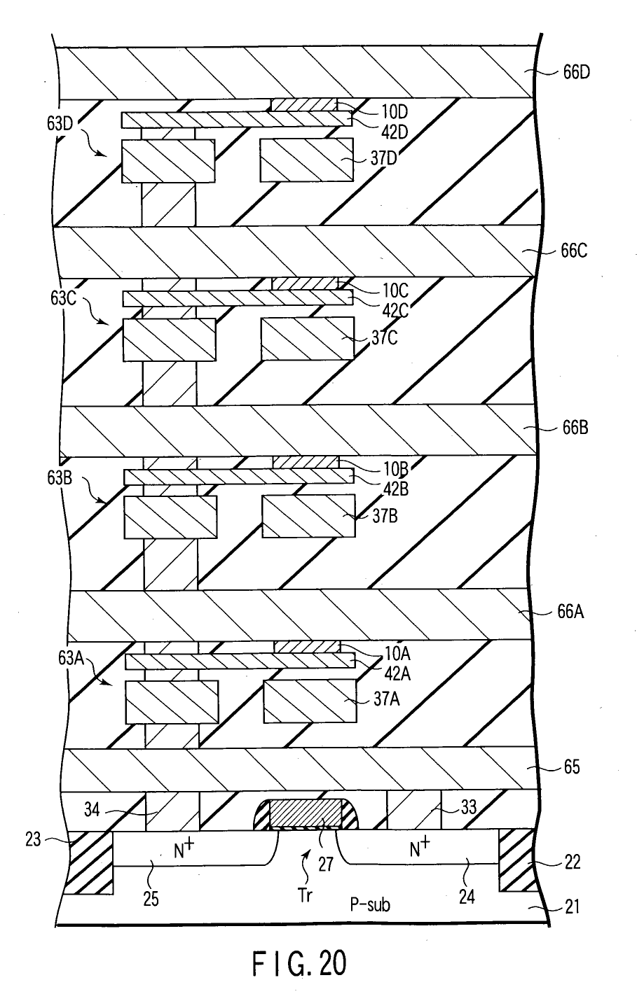

FIG. 20 is a cross-sectional view showing an example of the structure of each memory cell of a memory cell array, for illustrating a magnetic random access memory according to an eleventh embodiment of this invention. Like the cases of FIGS. 14A, 15 to 19, the memory cell is called a stacked type cell. The present embodiment is similar to the fifth to tenth embodiments in that four TMR elements 10A to 10D are stacked. In the present embodiment, the TMR elements 10A to 10D are respectively connected to bit lines which are arranged in position corresponding to the TMR elements. Further, data lines are respectively arranged between write word lines and read word lines.

That is, a data line 65 formed of a first-layered metal wiring, a write word line 37A formed of a second-layered metal wiring, a third-layered metal wiring 42A, the TMR element 10A, a fourth-layered bit line 66A, a write word line 37B formed of a fifth-layered metal wiring, a sixth-layered metal wiring 42B, the TMR element 10B, a bit line 66B formed of a seventh-layered metal wiring, a write word line 37C formed of an eighth-layered metal wiring, a ninth-layered metal wiring 42C, the TMR element 10C, a bit line 66C formed of a tenth-layered metal wiring, a write word line 37D formed of an eleventh-layered metal wiring, a twelfth-layered metal wiring 42D, the TMR element 10D, and a bit line 66D formed of a thirteenth-layered metal wiring are sequentially laminated via inter-level insulating films above a read word line 27 used as the gate electrode of the MOSFET Tr.

The TMR element 10A is sandwiched between the third-layered metal wiring 42A and the bit line 66A and is electrically connected to the wiring 42A and bit line 66A. The TMR element 10B is sandwiched between the sixth-layered metal wiring 42B and the bit line 66B and is electrically connected to the wiring 42B and bit line 66B. The TMR element 10C is sandwiched between the ninth-layered metal wiring 42C and the bit line 66C and is electrically connected to the wiring 42C and bit line 66C. The TMR element 10D is sandwiched between the twelfth-layered metal wiring 42D and the bit line 66D and is electrically connected to the wiring 42D and bit line 66D.

The third-layered metal wiring 42A is electrically connected to the drain of the MOSFET Tr via a contact 63A. The sixth-layered metal wiring 60B is electrically connected to a contact 63B. The ninth-layered metal wiring 42C is electrically connected to a contact 63C. The twelfth-layered metal wiring 42D is electrically connected to a contact 63D. The contacts 63A to 63D are connected together.

With the above structure, the data write/read operation is basically the same as that of the memory cells shown in FIGS. 13A, 14A, 15 to 19.

Further, potential of the node N of the sense amplifier 50 is set higher than Vh by a voltage drop due to the sum of the ON resistance of the column selection gate CSG and the ON resistance of the MOSFET Tr. Therefore, voltage applied across the series circuit of the MOSFET Tr and TMR elements 10A to 10D is set higher than Vh by a voltage drop due to the ON resistance of the MOSFET Tr. As a result, voltage applied across the TMR elements 10A to 10D becomes equal to Vh.

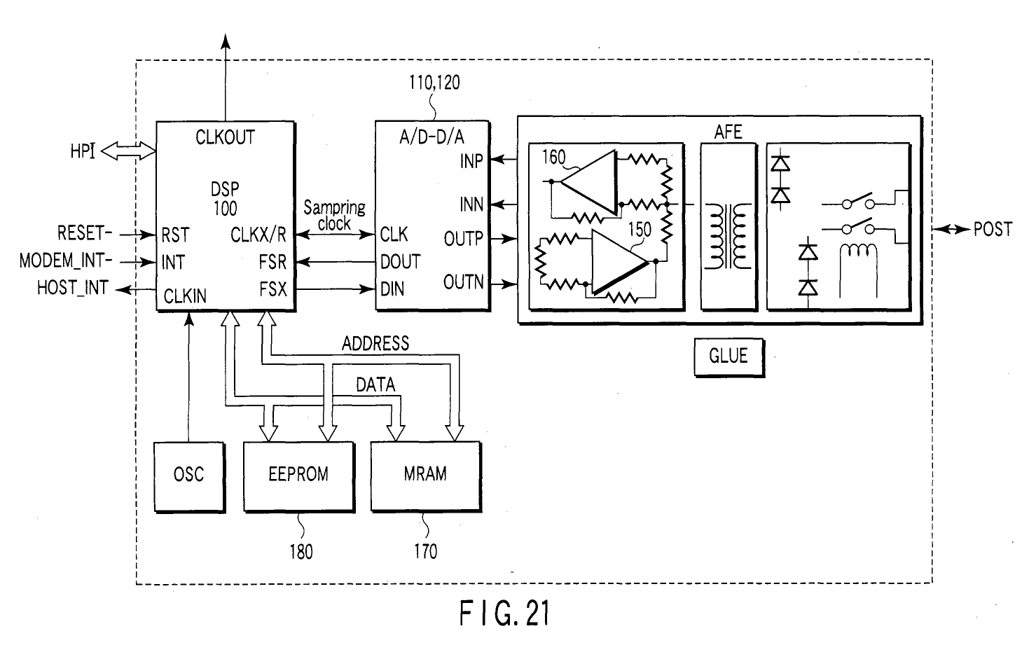

The magnetic random access memory (semiconductor memory device) according to the first to eleventh embodiments of this invention can be applied to various devices. Some of the application examples are explained with reference to FIGS. 21 to 27.

### Application Example 1

FIG. 21 shows an extracted DSL data path portion of a modem for digital subscriber lines (DSL). The modem includes a programmable digital signal processor (DSP) 100, analog/digital (A/D) converter 110, digital/analog (D/A) converter 120, transmission driver 150 and receiver amplifier 160. In FIG. 21, a band pass filter is omitted and a magnetic random access memory 170 and EEPROM 180 of this embodiment are shown as various types of optional memories used to hold a line code program (a program which permits a modem to be selected and operated according to coded subscriber line information and transfer condition (line code; OAM, CAP, RSK, FM, AM, PAM, DWMT and the like) performed by use of the DSP) instead of the band pass filter.

In the present example, two types of memories of the magnetic random access memory 170 and EEPROM 180 are used as a memory to hole the line code program. However, the EEPROM 180 can be replaced by a magnetic random access memory. That is, instead of using two types of memories, only the magnetic random access memory can be used.

### Application Example 1

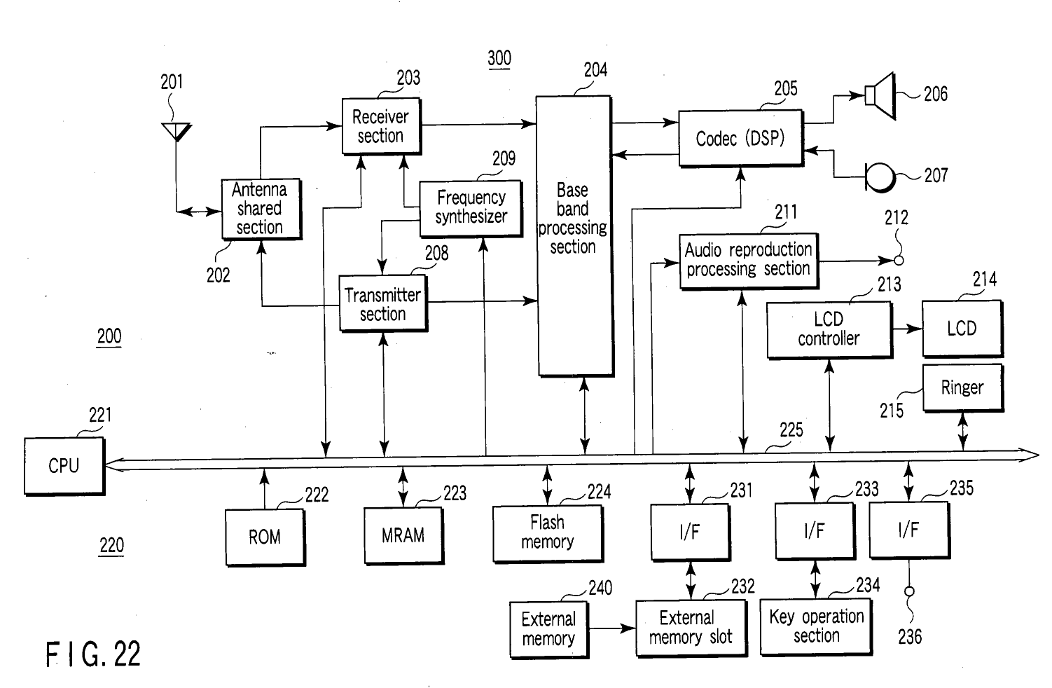

FIG. 22 shows a portable telephone terminal 300 as another application example. A communication section 200 which realizes the communication function includes a transmission/reception antenna 201, antenna shared section 202, receiver section 203, base band processing section 204, DSP 205 used as a voice codec, speaker (receiver) 206, microphone (transmitter) 207, transmitter section 208 and frequency synthesizer 209.

Further, the portable telephone terminal 300 includes a control section 220 which controls various sections of the portable telephone terminal. The control section 220 is a microcomputer to which a CPU 221, ROM 222, a magnetic random access memory (MRAM) 223 of this embodiment and flash memory 224 are connected via a CPU bus 225. A program executed by the CPU 221 and necessary data for display fonts are previously stored in the ROM 222. The MRAM 223 is mainly used as a working area. It is used to store data obtained in the course of calculations as required while the CPU 221 is executing the program or temporarily store data transferred between the control section 220 and the other sections. Further, when the power supply of the portable telephone terminal 300 is turned OFF, it is desired in some cases to store the set condition obtained immediately before turn-OFF of the power supply and set the same condition when the power supply is next turned ON. For this purpose, the flash memory 224 is used to store set parameters associated with the set condition. Thus, if the power supply of the portable telephone terminal is turned OFF, there is no possibility that the stored set parameters will be lost.

Further, the portable telephone terminal 300 includes an audio reproduction processing section 211, external output terminal 212, LCD controller 213, LCD (liquid crystal display) 214 and a ringer 215 which generates a call sound. The audio reproduction processing section 211 reproduces audio information input to the portable telephone terminal 300 (or audio information stored in an external memory 240 which will be described later). The reproduced audio information is transmitted to a head phone or mobile speaker via the external output terminal 212 and thus can be output to the exterior. Thus, by providing the audio reproduction processing section 211, audio information can be reproduced. For example, the LCD controller 213 receives display information from the CPU 221 via the CPU bus 225, converts the display information into LCD control information used to control the LCD 214 and drives the LCD 214 for display.

In addition, the portable telephone terminal 300 includes interface circuits (I/F) 231, 233, 235, external memory 240, external memory slot 232, key operation section 234 and external input/output terminal 236. A memory card such as the external memory 240 is inserted into the external memory slot 232. The external memory slot 232 is connected to the CPU bus 225 via the interface circuit (I/F) 231. Thus, by providing the slot 232 in the portable telephone terminal 300, it becomes possible to write information in the internal portion of the portable telephone terminal 300 into the external memory 240 and input information (for example, audio information) stored in the external memory 240 to the portable telephone terminal 300. The key operation section 234 is connected to the CPU bus 225 via the interface circuit (I/F) 233. Key input information input from the key operation section 234 is transmitted to the CPU 221, for example. The external input/output terminal 236 is connected to the CPU bus 225 via the interface circuit (I/F) 235. Thus, the terminal 236 functions as a terminal which inputs various information items from the exterior to the portable telephone terminal 300 or outputs information from the portable telephone terminal 300 to the exterior.

In this application example, the ROM 222, RAM 223 and flash memory 224 are used, but it is possible to replace the flash memory 224 by a magnetic random access memory and further replace the ROM 222 by a magnetic random access memory.

### Application Example 3

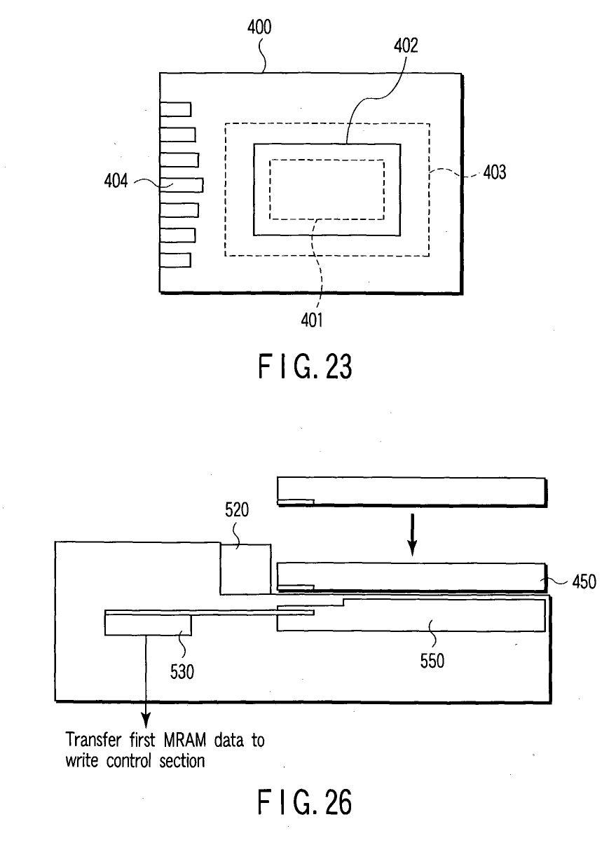

FIGS. 23 to 27 show examples in which a magnetic random access memory is applied to cards (MRAM cards) which receive media contents such as smart media or the like.

An MRAM chip 401 is contained in an MRAM card body 400. An opening portion 402 corresponding in position to the MRAM chip 401 is formed in the card body 400 so as to expose the MRAM chip 401. A shutter 403 is provided on the opening portion 402 so that the MRAM chip 401 can be protected by the shutter 403 when the MRAM card is carried. The shutter 403 is formed of a material such as ceramic which has an effect of shielding external magnetic fields. When data is transferred, the shutter 403 is released to expose the MRAM chip 401. An external terminal 404 is used to output contents data stored in the MRAM card to the exterior.

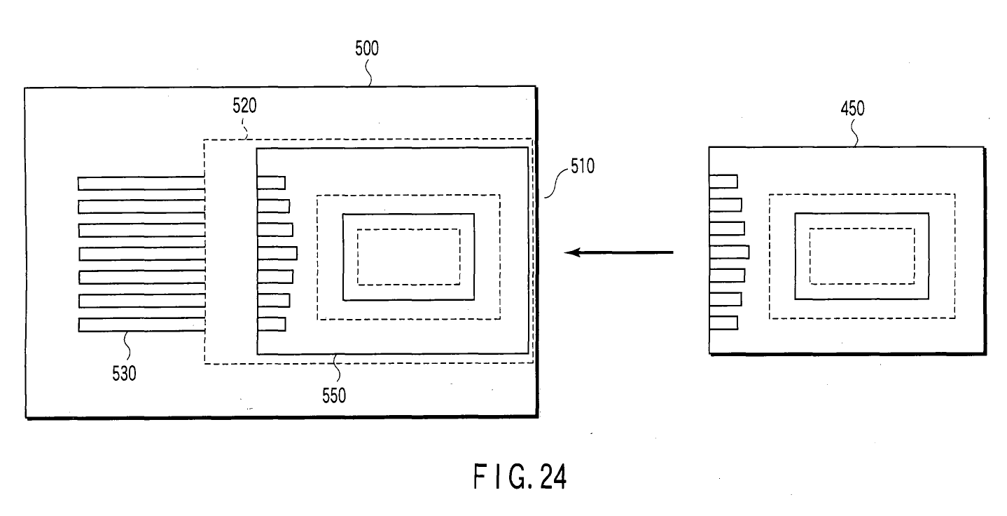

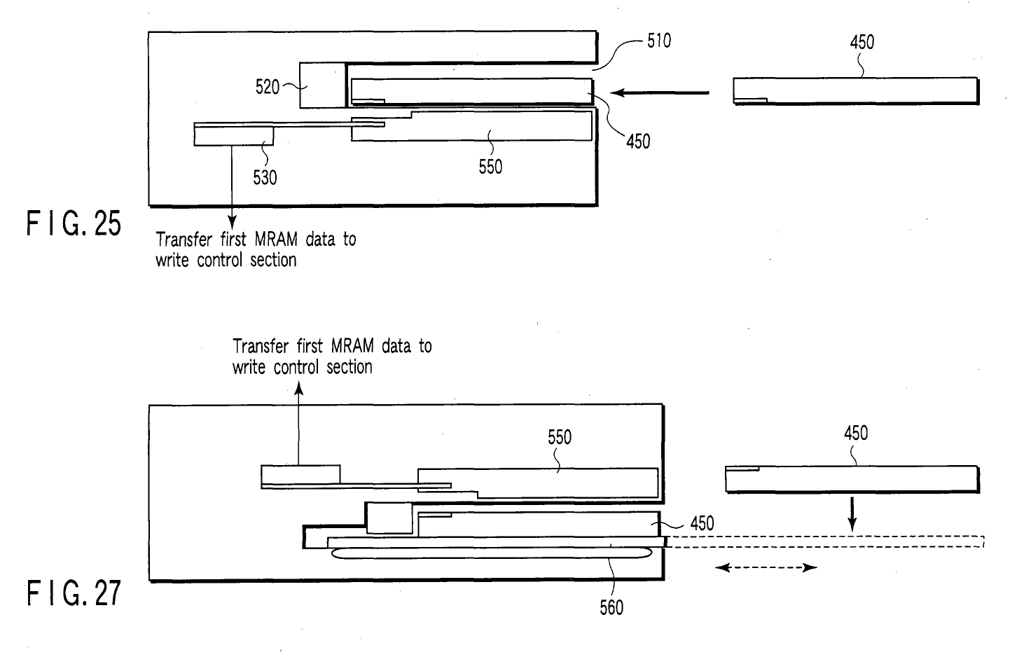

FIGS. 24 and 25 show a transfer device which transfers data to the MRAM card. FIG. 24 is a top plan view of a card insertion type transfer device and FIG. 25 is a cross-sectional view showing the transfer device. A second MRAM card 450 which an end user uses is inserted via an inserting portion 510 of a transfer device 500 as indicated by an arrow and pushed into the transfer device until it is stopped by a stopper 520.

The stopper 520 also functions as a member which aligns the second MRAM card 450 with a first MRAM 550. When the second MRAM card 450 is placed in a preset position, a control signal is supplied from a first MRA data rewriting control section to an external terminal 530. As a result, data stored in the first MRAM 550 is transferred to the second MRAM card 450.

FIG. 26 shows a fitting type transfer device. The transfer device is of a type in which the second MRAM card 450 is fitted into and mounted on the first MRAM 550 as indicated by an arrow with the stopper 520 used as a target. The data transfer method is the same as that of the card insertion type and the explanation thereof is omitted.

FIG. 27 shows a slide type transfer device. Like a CD-ROM driver or DVD driver, a transfer device 500 has a reception plate slide 560 and the reception plate slide 560 is moved in a direction as indicated by an arrow. When the reception plate slide 560 is moved to a position indicated by broken lines, the second MRAM card 450 is placed on the reception plate slide 560 and then inserted into the transfer device 500. The fact that the second MRAM 450 is inserted and the front end portion thereof abuts against the stopper 520 and the data transfer method are the same as those of the card insertion type and the explanation thereof is omitted.

As described above, according to one aspect of this invention, a magnetic random access memory can be attained in which the read margin can be made large since voltage applied across a series circuit of the TMR element and selection element can be set high while a lowering in the MR ratio of the TMR element is suppressed.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A magnetic random access memory comprising:
memory cells each including at least one tunneling magnetoresistive element which stores information by use of a tunneling magnetoresistive effect and a selection element which selects the tunneling magnetoresistive element, and
a read circuit which reads information from the tunneling magnetoresistive element by applying read voltage to the memory cell and causing a current to flow through the tunneling magnetoresistive element via the selection element,
wherein the read circuit includes a voltage setting section used to apply voltage which makes a resistance variation rate of the tunneling magneto-resistive element substantially equal to half a resistance variation rate thereof obtained when 0 V is applied across the tunneling magnetoresistive element to the tunneling magnetoresistive element at the information read time.

2. A magnetic random access memory according to claim 1, in which the memory cells are arranged in a matrix form and which further comprises word lines each connected to control electrodes of those of the selection elements of the memory cells which are arranged on a corresponding one of rows and bit lines each connected to one-side ends of those of the tunneling magnetoresistive elements of the memory cells which are arranged on a corresponding one of columns, wherein the read circuit includes a current specifying section which specifies a current flowing through the memory cell, and a comparator section which compares potential corresponding to an intermediate value between “1” and “0” of storage information in the bit line with potential read from the memory cell to read the storage information.

3. A magnetic random access memory according to claim 1, wherein each of the memory cells includes a plurality of tunneling magnetoresistive elements and the other ends of the tunneling magnetoresistive elements of each memory cell are connected to one end of the current path of the selection element.

4. A magnetic random access memory according to claim 2, wherein the selection element is a MOSFET and the control electrode is a gate electrode thereof.

5. A magnetic random access memory according to claim 2, wherein the selection element is a bipolar transistor and the control electrode is a base electrode thereof.

6. A magnetic random access memory according to claim 1, in which the selection element is a diode and the memory cells are arranged in a matrix form and which further comprises word lines each connected to cathodes of those of the diodes which are arranged on a corresponding one of rows and bit lines each connected to one-side ends of those of the tunneling magnetoresistive elements of the memory cells which are arranged on a corresponding one of columns, wherein the read circuit includes a current specifying section which specifies a current flowing through the memory cell, and a comparator section which compares potential corresponding to an intermediate value between “1” and “0” of storage information in the bit line with potential read from the memory cell to read the storage information.

7. A magnetic random access memory according to claim 6, wherein each of the memory cells includes a plurality of tunneling magnetoresistive elements and the other ends of the tunneling magnetoresistive elements of each memory cell are connected to an anode of the diode.

8. A magnetic random access memory according to claim 3, wherein at least two of the plurality of tunneling magnetoresistive elements connected to the selection element are connected in parallel.

9. A magnetic random access memory according to claim 3, wherein at least two of the plurality of tunneling magnetoresistive elements connected to the selection elements are connected in series.

10. A magnetic random access memory comprising:
memory cells each including at least one tunneling magnetoresistive element which stores information by use of a tunneling magnetoresistive effect and a selection element which selects the tunneling magnetoresistive element, and
a read circuit which reads information from the tunneling magnetoresistive element by applying read voltage to the memory cell and causing a current to flow through the tunneling magnetoresistive element via the selection element,
wherein the read circuit includes a voltage setting section used to apply voltage which is higher than the voltage applied to the tunneling magneto-resistive element by at least a voltage drop occurring across the selection element to the tunneling magnetoresistive element at the information read time.

11. A magnetic random access memory according to claim 10, in which the memory cells are arranged in a matrix form and which further comprises word lines each connected to control gates of those of the selection elements of the memory cells which are arranged on a corresponding one of rows and bit lines each connected to one-side ends of the tunneling magnetoresistive elements of the memory cells which are arranged on corresponding one of columns, wherein the read circuit includes a current specifying section which specifies a current flowing through the memory cell, and a comparator section which compares potential corresponding to an intermediate value between “1” and “0” of storage information in the bit line with potential read from the memory cell to read the storage information.

12. A magnetic random access memory according to claim 10, wherein each of the memory cells includes a plurality of tunneling magnetoresistive elements and the other ends of the tunneling magnetoresistive elements of each memory cell are connected to one end of the current path of the selection element.

13. A magnetic random access memory according to claim 11, wherein the selection element is a MOSFET and the control electrode is a gate electrode thereof.

14. A magnetic random access memory according to claim 11, wherein the selection element is a bipolar transistor and the control electrode is a base electrode thereof.

15. A magnetic random access memory according to claim 10, in which the selection element is a diode and the memory cells are arranged in a matrix form and which further comprises word lines each connected to cathodes of those of the diodes which are arranged on a corresponding one of rows and bit lines each connected to one-side ends of those of the tunneling magneto-resistive elements of the memory cells which are arranged on a corresponding one of columns, wherein the read circuit includes a current specifying section which specifies a current flowing through the memory cell, and a comparator section which compares potential corresponding to an intermediate value between “1” and “0” of storage information in the bit line with potential read from the memory cell to read the storage information.

16. A magnetic random access memory according to claim 15, wherein each of the memory cells includes a plurality of tunneling magnetoresistive elements and the other ends of the tunneling magnetoresistive elements of each memory cell are connected to an anode of the diode.

17. A magnetic random access memory according to claim 12, wherein at least two of the plurality of tunneling magnetoresistive elements connected to the selection elements are connected in parallel.

18. A magnetic random access memory according to claim 12, wherein at least two of the plurality of tunneling magnetoresistive elements connected to the selection element are connected in series.

19. A magnetic random access memory comprising:
tunneling magnetoresistive elements which store information by use of a tunneling magnetoresistive effect,
bit lines connected to one-side ends of the tunneling magnetoresistive elements,
word lines connected to the other ends of the tunneling magnetoresistive elements, and
a read circuit which reads information from the tunneling magnetoresistive element by applying read voltage to the tunneling magnetoresistive elements and causing a current to flow through the tunneling magnetoresistive element,
wherein the read circuit includes a voltage setting section used to apply voltage which makes a resistance variation rate of the tunneling magnetoresistive element substantially equal to half a resistance variation rate thereof obtained when 0 V is applied across the tunneling magnetoresistive element to the tunneling magnetoresistive element at the information read time.

20. A magnetic random access memory according to claim 19, wherein the tunneling magnetoresistive elements are arranged in a matrix form and the read circuit includes a current specifying section which specifies a current flowing through the tunneling magnetoresistive element and a comparator section which compares potential corresponding to an intermediate value between “1” and “0” of storage information in the bit line with potential read from the tunneling magnetoresistive element to read the storage information.

21. A magnetic random access memory according to claim 20, wherein the bit lines are arranged above the tunneling magnetoresistive elements.

22. A magnetic random access memory according to claim 21, wherein the bit lines are arranged below the tunneling magnetoresistive elements.

23. A magnetic random access memory according to claim 20, wherein the word lines are arranged above the tunneling magnetoresistive elements.

24. A magnetic random access memory according to claim 20, wherein the word lines are arranged below the tunneling magnetoresistive elements.
